(19) United States
(12) Patent Application Publication
(10) Pub. No.: US 2025/0266796 A1
(43) Pub. Date: Aug. 21, 2025

(54) RADIO-FREQUENCY CIRCUIT

(71) Applicant: Murata Manufacturing Co., Ltd., Nagaokakyo-shi (JP)

(72) Inventor: Isao TAKENAKA, Nagaokakyo-shi, Kyoto (JP)

(73) Assignee: Murata Manufacturing Co., Ltd., Nagaokakyo-shi (JP)

(21) Appl. No.: 19/019,571

(22) Filed: Jan. 14, 2025

(30) Foreign Application Priority Data
Feb. 16, 2024 (JP) 2024-021873

(51) Int. Cl. H03F 3/24; H03H 7/18

(52) U.S. Cl. CPC H03F 3/245; H03H 7/18; H03F 2200/171; H03F 2200/451

(57) ABSTRACT

A radio-frequency circuit includes: a power amplifier to which a first signal is input; a power amplifier to which a second signal that is +90° with respect to the first signal is input; a combiner circuit that combines in phase a third signal in band A input from a fourth input end and a fourth signal in band A input from a fifth input end; a phase-shifting circuit connected to a third output end of the power amplifier; a phase-shifting circuit that is connected to a fourth output end of the power amplifier and sets a passband phase of a signal in band A to −90° with respect to the phase-shifting circuit; a filter that has a passband containing a transmission band of band A; and a filter that has a passband containing a reception band of band B that can be transmitted simultaneously with band A.

### CROSS-REFERENCE TO RELATED APPLICATION

This application claims priority to Japanese Patent Application No. JP 2024-021873 filed on Feb. 16, 2024. The entire contents of the above-identified applications, including the specifications, drawings and claims, are incorporated herein by reference in their entirety.

### BACKGROUND OF THE DISCLOSURE

### 1. Field of the Disclosure

The present disclosure relates to a radio-frequency circuit.

### 2. Description of the Related Art

Japanese Unexamined Patent Application Publication No. 2012-147352 discloses a semiconductor device (radio-frequency (RF) circuit) including: a first amplifier and a second amplifier constituting a balanced amplifier; a first phase-shifting circuit arranged in a first output path connecting an output end of the first amplifier and an output terminal; a second phase-shifting circuit arranged in a second output path connecting an output end of the second amplifier and the output terminal; a resistor connected to an output end of the first phase-shifting circuit and an output end of the second phase-shifting circuit; a first inductor connected between the output end of the first phase-shifting circuit and the output terminal; and a second inductor connected between the output end of the second phase-shifting circuit and the output terminal. Accordingly, the power combining loss in a power coupler composed of the resistor, the first inductor, and the second inductor can be reduced.

### SUMMARY OF THE DISCLOSURE

In RF circuits that simultaneously transmit transmission signals and reception signals, there is a need to improve the isolation between transmission and reception, along with highly efficient power combining against load fluctuations.

Accordingly, it is an feature of the present disclosure to provide a radio-frequency circuit that achieves highly efficient power combining as well as improved isolation between transmission and reception.

To achieve the above-mentioned feature, a radio-frequency circuit according to one aspect of the present disclosure includes: a first antenna terminal; a splitter that has a first input end, a first output end, and a second output end, and is configured to separate a signal in a transmission band of a first band input to the first input end to output a first sub-band signal from the first output end and output a second sub-band signal from the second output end, the second sub-band signal having a phase relatively +90° with respect to the first sub-band signal; a first power amplifier that has a second input end and a third output end, the second input end connected to the first output end; a second power amplifier that has a third input end and a fourth output end, the third input end connected to the second output end; a combiner circuit that has a fourth input end, a fifth input end, and a fifth output end, and is configured to output, from the fifth output end, an output signal in the first band generated by combining in phase a third sub-band signal in the first band input from the fourth input end and a fourth sub-band signal in the first band input from the fifth input end; a first phase-shifting circuit connected between the third output end and the fourth input end; a second phase-shifting circuit that is connected between the fourth output end and the fifth input end, and is configured such that a passband phase of the signal in the transmission band of the first band becomes relatively −90° with respect to the first phase-shifting circuit; a first filter that is connected between the fifth output end and the first antenna terminal or between the first phase-shifting circuit and the fourth input end, and has a passband containing the transmission band of the first band; and a second filter that is connected to a path connecting the first antenna terminal and the first filter, and has a passband containing a reception band of a second band that can be transmitted simultaneously with the first band, wherein the first phase-shifting circuit and the second phase-shifting circuit are configured such that a difference between a first reflection phase in the reception band of the second band upon viewing the fifth output end from the third output end and a second reflection phase in the reception band of the second band upon viewing the fifth output end from the fourth output end becomes 180°.

Additionally, a radio-frequency circuit according to one aspect of the present disclosure includes: a first antenna terminal; a combiner that has a first output end, a first input end, and a second input end, and is configured to combine a first signal in a reception band of a first band input to the first input end and a second signal in the reception band of the first band input to the second input end, the second signal having a phase relatively +90° with respect to the first signal, and output a combined signal from the first output end; a first low-noise amplifier that has a second output end and a third input end, the second output end connected to the first input end; a second low-noise amplifier that has a third output end and a fourth input end, the third output end connected to the second input end; a splitter circuit that has a fourth output end, a fifth output end, and a fifth input end, and is configured to distribute power of a reception signal in the reception band of the first band input to the fifth input end to the fourth output end and the fifth output end; a first phase-shifting circuit connected between the third input end and the fourth output end; a second phase-shifting circuit that is connected between the fourth input end and the fifth output end, and is configured such that a passband phase in the reception band of the first band becomes relatively −90° with respect to the first phase-shifting circuit; a first filter that is connected between the fifth input end and the first antenna terminal or between the first phase-shifting circuit and the fourth output end, and has a passband containing the reception band of the first band; and a second filter that is connected to a path connecting the first antenna terminal and the first filter, and has a passband containing a transmission band of a second band that can be transmitted simultaneously with the first band, wherein the first phase-shifting circuit and the second phase-shifting circuit are configured such that a difference between a first reflection phase in the transmission band of the second band upon viewing the fifth input end from the third input end and a second reflection phase in the transmission band of the second band upon viewing the fifth input end from the fourth input end becomes 180°.

According to the present disclosure, a radio-frequency circuit that achieves highly efficient power combining as well as improved isolation between transmission and reception can be provided.

### BRIEF DESCRIPTION OF THE DRAWINGS

FIG. 1 is a circuit configuration diagram of an amplifier circuit, a radio-frequency (RF) circuit, and a communication device according to an embodiment;

FIG. 2 is a circuit state diagram illustrating the RF circuit in a first mode according to the embodiment;

FIG. 3 includes a Smith chart representing the transmission bandpass characteristics as well as the impedance in the reception band of an RF circuit according to a first embodiment and a comparative example;

FIG. 4 is a circuit state diagram illustrating the RF circuit in a second mode according to the embodiment;

FIG. 5 is a circuit state diagram illustrating the RF circuit in a third mode according to the embodiment;

FIG. 6 is a circuit configuration diagram of an amplifier circuit, an RF circuit, and a communication device according to a first modification of the embodiment;

FIG. 7A is a circuit state diagram illustrating an RF circuit in the first mode according to a second modification of the embodiment;

FIG. 7B is a circuit state diagram illustrating the RF circuit in the second mode according to the second modification of the embodiment; and

FIG. 8 includes a plan view and a cross-sectional view of the RF circuit according to the second modification of the embodiment.

### DESCRIPTION OF THE PREFERRED EMBODIMENTS

Hereinafter, an embodiment of the present disclosure will be described in detail using the drawings. The embodiment described hereinafter is all illustrative of comprehensive or specific examples. The numerical values, shapes, materials, components, and component arrangement and connection forms discussed in the following embodiment are merely examples and are not intended to limit the scope of the present disclosure.

Note that each of the drawings is a schematic diagram that has been appropriately emphasized, omitted, or adjusted in scale to illustrate the present disclosure. Therefore, the drawings are not necessarily depicted with strict accuracy and may differ from the actual shapes, positional relationships, and proportions. In each of the drawings, the same reference numerals are assigned to substantially identical configurations, and overlapping descriptions may be omitted or simplified.

In each of the following drawings, the x-axis and the y-axis are axes orthogonal to each other on a plane parallel to the main surface of a mounting substrate. Specifically, in the case where the mounting substrate has a rectangular shape in plan view, the x-axis is parallel to a first side of the mounting substrate, and the y-axis is parallel to a second side orthogonal to the first side of the mounting substrate. Additionally, the z-axis is an axis perpendicular to the main surface of the mounting substrate, the positive direction of which indicates an upward direction and the negative direction of which indicates a downward direction.

In the component arrangement of the present disclosure, “the component is arranged on the substrate” includes both the arrangement of the component on the main surface of the substrate and the arrangement of the component within the substrate. “The component is arranged on the main surface of the substrate” includes not only the arrangement of the component in contact with the main surface of the substrate but also the arrangement of the component above the main surface without direct contact with the main surface (for example, upon the component is laminated or stacked on top of another component arranged in contact with the main surface). Additionally, it is acceptable that “the component is arranged on the main surface of the substrate” include the arrangement of the component in a recess formed in the main surface. “The component is arranged within the substrate” includes not only the encapsulation of the component within a module substrate but also the arrangement of the entire component between two main surfaces of the substrate, with part of the component not covered by the substrate, as well as the arrangement of only part of the component within the substrate.

Furthermore, in the component arrangement of the present disclosure, “plan view of the main surface” refers to the orthogonal projection of an feature onto the xy-plane as viewed from the positive side of the z-axis. “A overlaps with B in plan view” means that at least part of the region of A projected orthogonally onto the xy-plane overlaps with at least part of the region of B projected orthogonally onto the xy-plane. In addition, “A is arranged between B and C” means that at least one of line segments connecting any point in B and any point in C passes through A.

Furthermore, in the present disclosure, terms indicating the relationship between elements, such as parallel and vertical, terms indicating the shape of elements, such as rectangular shapes, and numerical ranges do not solely represent strict meanings but also encompass substantially equivalent ranges, including differences of a few percent, for example.

In the circuit configuration of the present disclosure, “connected” refers not only to direct connections by connection terminals and/or wiring conductors but also to cases where an electrical connection is made with another circuit element interposed therebetween. “Connected between A and B” means connected to both A and B between A and B.

Also, in the present disclosure, “path” refers to a transmission line composed of wiring through which a radio-frequency (RF) signal propagates, an electrode directly connected to the wiring, and a terminal directly connected to the wiring or the electrode.

Additionally, in the present disclosure, “component A is arranged in series in path B” means that both the signal input end and the signal output end of component A are connected to wiring, an electrode, or a terminal constituting path B.

In the present disclosure, “terminal”, “input end”, and “output end” refer to the point at which a conductor within an element ends. Note that, assuming the impedance of a conductor between elements is sufficiently low, a terminal is interpreted not only as a single point but also as any point on the conductor between the elements or as the entire conductor.

Also, terms indicating the relationship between elements, such as “parallel” and “vertical”, terms indicating the shape of elements, such as “rectangular shapes”, and numerical ranges do not solely represent strict meanings but also encompass substantially equivalent ranges, including differences of a few percent, for example.

“The passband of a filter” is a portion of the frequency spectrum transmitted by the filter, and is defined as the frequency range where the output power does not attenuate by more than 3 dB from the maximum output power. Therefore, the high and low ends of the passband of a bandpass filter are identified as the higher and lower frequencies of the two points at which the output power attenuates by 3 dB from the maximum output power.

“Transmission band” refers to the frequency band used for transmission in a communication device. “Reception band” refers to the frequency band used for reception in a communication device. For example, frequency division duplex (FDD) uses frequency bands that are different from each other as the transmission band and the reception band, and time division duplex (TDD) uses the same frequency band for the transmission band and the reception band. In particular, in FDD, upon a communication device is implemented in user equipment (UE) in a cellular network, the uplink band (uplink operation band) is used as the transmission band, while the downlink band (downlink operation band) is used as the reception band. In contrast, upon a communication device is implemented as a base station (BS) in a cellular network, the downlink band is used as the transmission band, while the uplink band is used as the reception band.

The “passband phase” between two terminals of an RF signal is obtained by applying a measuring RF probe to the two terminals and measuring the bandpass characteristics (S21) with a network analyzer. In addition, the “reflection phase” at one terminal of an RF signal is obtained by applying a measuring RF probe to the one terminal and measuring the bandpass characteristics (S11) with a network analyzer.

In the present disclosure, the numerical values of passband phase, reflection phase, and reflection phase difference do not solely represent strict meanings but also encompass substantially equivalent ranges, including differences of approximately 30%, for example.

### EMBODIMENT

### 1 Circuit Configuration of Amplifier Circuit, Radio-Frequency Circuit, and Communication Device

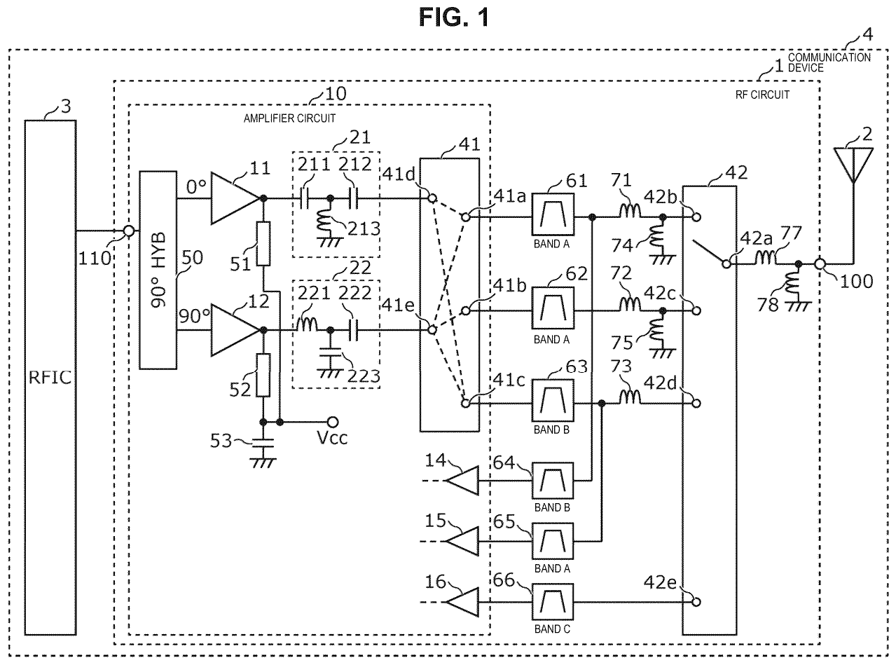

The circuit configuration of an amplifier circuit 10, a radio-frequency (RF) circuit 1, and a communication device 4 according to the present embodiment will be described with reference to FIG. 1. FIG. 1 is a circuit configuration diagram of the amplifier circuit 10, the RF circuit 1, and the communication device 4 according to the embodiment.

### 1.1 Circuit Configuration of Communication Device 4

First, the circuit configuration of the communication device 4 will be described. As illustrated in FIG. 1, the communication device 4 according to the present embodiment includes the RF circuit 1, an antenna 2, and an RF signal processing circuit (RFIC: Radio Frequency Integrated Circuit) 3.

The RF circuit 1 transmits RF signals between the antenna 2 and the RFIC 3. The detailed circuit configuration of the RF circuit 1 will be described later.

The antenna 2 is connected to an antenna connection terminal 100 (first antenna terminal) of the RF circuit 1. The antenna 2 transmits an RF signal output from the RF circuit 1. The antenna 2 also receives an RF signal from the outside and outputs it to the RF circuit 1.

The RFIC 3 is an example of a signal processing circuit that processes RF signals. Specifically, the RFIC 3 applies signal processing, such as upconverting or the like, to a transmission signal input from a baseband signal processing circuit (BBIC, not illustrated), and outputs the transmission signal generated by the signal processing to a transmission path of the RF circuit 1. In addition, the RFIC 3 applies signal processing, such as downconverting or the like, to a reception signal input via a reception path of the RF circuit 1, and outputs the reception signal generated by the signal processing to the BBIC. The RFIC 3 also has a control unit that controls the RF circuit 1. Note that the function of the RFIC 3 as the control unit, either partially or entirely, may be implemented outside of the RFIC 3, such as in the BBIC or in the RF circuit 1.

The RFIC 3 also has the function as a control unit that controls a power supply voltage Vcc and bias current supplied to each amplifier included in the amplifier circuit 10. Specifically, the RFIC 3 outputs a control signal to a power supply circuit (not illustrated) and a bias circuit (not illustrated). Note that the power supply circuit and the bias circuit may be arranged in the RF circuit 1 or the amplifier circuit 10. Each amplifier in the amplifier circuit 10 is supplied with the power supply voltage Vcc controlled by the above-mentioned control signal from the power supply circuit, and is also supplied with a bias current controlled by the above-mentioned control signal from the bias circuit.

The RFIC 3 also has the function as a control unit that controls the connection of switch circuits 41 and 42 included in the RF circuit 1 based on the frequency band used or the like.

Note that the antenna 2 is not an essential element in the communication device 4 according to the present embodiment.

### 1.2 Circuit Configuration of RF Circuit 1

Next, the circuit configuration of the RF circuit 1 will be described. As illustrated in FIG. 1, the RF circuit 1 includes the amplifier circuit 10, filters 61, 62, 63, 64, 65 and 66, the switch circuit 42, inductors 71 to 78, and the antenna connection terminal 100.

The amplifier circuit 10 is a circuit that amplifies transmission signals in band A and band B, input from an RF input terminal 110, and amplifies reception signals in band A and band B, input from the antenna connection terminal 100.

Note that, in the present embodiment, each of band A and band B refers to a frequency band predefined by a standardization organization (such as 3GPP (3rd Generation Partnership Project, registered trademark), IEEE (Institute of Electrical and Electronics Engineers), etc.) for communication systems built using radio access technology (RAT). In the present embodiment, the communication systems can be, for example, 4G (4th Generation)-LTE (Long Term Evolution) systems, 5G (5th Generation)-NR (New Radio) systems, WLAN (Wireless Local Area Network) systems, and the like, but are not limited to these.

The filter 61, which is an example of a first filter, is connected between the switch circuit 41 and the antenna connection terminal 100 and has a passband containing the transmission band of band A (first band). Specifically, one end of the filter 61 is connected to a terminal 41a of the switch circuit 41, and the other end of the filter 61 is connected to the antenna connection terminal 100 with the inductors 71 and 77 and the switch circuit 42 interposed therebetween.

The filter 62, which is an example of a fifth filter, is connected between a phase-shifting circuit 22 and the switch circuit 42 and has a passband containing the transmission band of band A (first band). Specifically, one end of the filter 62 is connected to a terminal 41b of the switch circuit 41, and the other end of the filter 62 is connected to a terminal 42c of the switch circuit 42 with the inductor 72 interposed therebetween.

The filter 63, which is an example of a third filter, is connected between the switch circuit 41 and the antenna connection terminal 100 and has a passband containing the transmission band of band B (second band). Specifically, one end of the filter 63 is connected to a terminal 41c of the switch circuit 41, and the other end of the filter 63 is connected to the antenna connection terminal 100 with the inductors 73 and 77 and the switch circuit 42 interposed therebetween.

The filter 64, which is an example of a second filter, has a passband containing the reception band of band B (second band). One end of the filter 64 is connected to the path connecting the antenna connection terminal 100 and the filter 61, and the other end is connected to an input end of a low-noise amplifier 14.

The filter 65, which is an example of a fourth filter, has a passband containing the reception band of band A (first band). One end of the filter 65 is connected to the path connecting the antenna connection terminal 100 and the filter 63, and the other end is connected to an input end of a low-noise amplifier 15.

The filter 66 has a passband containing the reception band of band C. One end of the filter 66 is connected to a terminal 42e of the switch circuit 42, and the other end is connected to an input end of a low-noise amplifier 16.

Note that the low-noise amplifiers connected to the filters 64 to 66 may be included in the amplifier circuit 10.

Band A (first band) and band B (second band) are a combination of bands allowing simultaneous transmission. Note that each of band A (first band) and band B (second band) may be a band using time-division duplexing (TDD). In this case, the filters 61 to 65 may have the same passband.

Band A is, for example, band B41 for 4G-LTE or band n41 for 5G-NR, while band B is, for example, band B40 for 4G-LTE or band n40 for 5G-NR.

The switch circuit 42, which is an example of an antenna switch, has terminals 42a, 42b, 42c, 42d, and 42e. The terminal 42a is connected to the antenna connection terminal 100 with the inductor 77 interposed therebetween; the terminal 42b is connected to the filters 61 and 64 with the inductor 71 interposed therebetween; the terminal 42c is connected to the filter 62 with the inductor 72 interposed therebetween; the terminal 42d is connected to the filters 63 and 65 with the inductor 73 interposed therebetween; and the terminal 42e is connected to the filter 66.

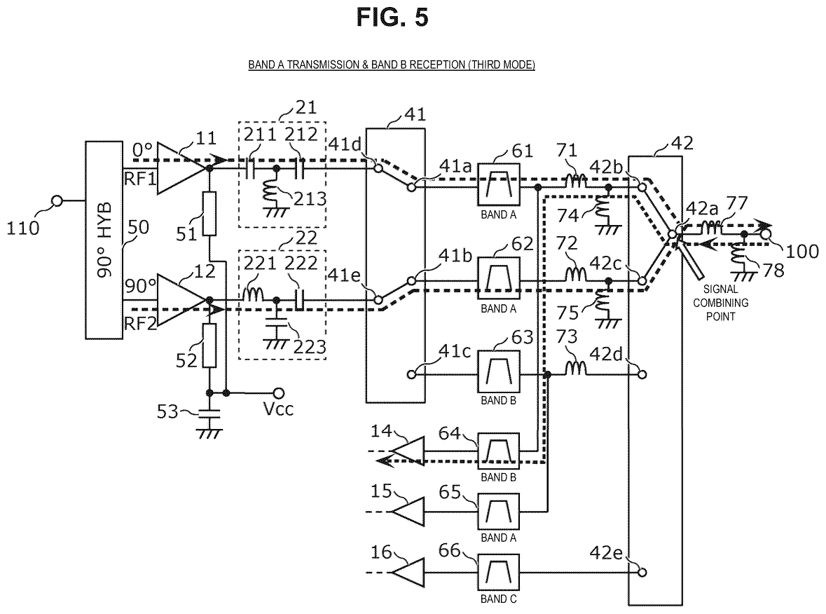

Note that, in the case where the RF circuit 1 operates in a later-described third mode (see FIG. 5), the switch circuit 42 corresponds to a combiner circuit. In the case of the third mode, the terminal 42b corresponds to a fourth input end, the terminal 42c corresponds to a fifth input end, and the terminal 42a corresponds to a fifth output end.

With the above-mentioned configuration, the switch circuit 42 switches between the connection and disconnection between the antenna connection terminal 100 and the filters 61 and 64, switches between the connection and disconnection between the antenna connection terminal 100 and the filter 62, switches between the connection and disconnection between the antenna connection terminal 100 and the filters 63 and 65, and switches between the connection and disconnection between the antenna connection terminal 100 and the filter 66.

The inductor 71 is arranged in series in the path connecting the terminal 42b and the filters 61 and 64. The inductor 74 is connected between the above-mentioned path and ground. The inductors 71 and 74 perform impedance matching between the switch circuit 42 and the filters 61 and 64. The inductor 72 is arranged in series in the path connecting the terminal 42c and the filter 62. The inductor 75 is connected between the above-mentioned path and ground. The inductors 72 and 75 perform impedance matching between the switch circuit 42 and the filter 62. The inductor 73 is arranged in series in the path connecting the terminal 42d and the filters 63 and 65. The inductor 76 is connected between the above-mentioned path and ground. The inductors 73 and 76 perform impedance matching between the switch circuit 42 and the filters 63 and 65. The inductor 77 is arranged in series in the path connecting the terminal 42a and the antenna connection terminal 100. The inductor 78 is connected between the above-mentioned path and ground. The inductors 77 and 78 perform impedance matching between the switch circuit 42 and the antenna 2. Note that at least one of the inductors 71 to 78 may be omitted.

According to the above-mentioned circuit configuration, the RF circuit 1 can perform simultaneous transmission of the transmission signal in band A and the reception signal in band B, as well as simultaneous transmission of the transmission signal in band B and the reception signal in band A.

Note that it is only necessary for the RF circuit 1 according to the present disclosure to have at least the amplifier circuit 10 and the filters 61 and 64 in the circuit configuration illustrated in FIG. 1.

### 1.3 Circuit Configuration of Amplifier Circuit 10

Next, the circuit configuration of the amplifier circuit 10 will be described in detail.

As illustrated in FIG. 1, the amplifier circuit 10 includes power amplifiers 11 and 12, phase-shifting circuits 21 and 22, the switch circuit 41, a 90° hybrid 50, phase-shifting lines 51 and 52, a capacitor 53, the RF input terminal 110, and the low-noise amplifiers 14, 15 and 16.

The RF input terminal 110 is connected to the RFIC 3. Note that the RF input terminal 110 and the antenna connection terminal 100 each may be a metal conductor such as a metal electrode and a metal bump, or may be a single point (node) on the metal wiring.

The 90° hybrid 50, which is an example of a splitter, has a first input end, a first output end, and a second output end, the first input end connected to the RF input terminal 110, the first output end connected to a second input end of the power amplifier 11, and the second output end connected to a third input end of the power amplifier 12. The 90° hybrid 50 is configured to separate the fundamental wave signal in the transmission band of band A or band B, which is input to the first input end, to output a first sub-band signal RF1 from the first output end, and to output a second sub-band signal RF2 from the second output end, the second sub-band signal having a phase relatively +90° with respect to the first sub-band signal RF1.

Note that, instead of the 90° hybrid 50, a phase-shifting circuit having other circuit configuration may be arranged.

The power amplifier 11, which is an example of a first power amplifier, has the second input end and a third output end, the second input end connected to the first output end of the 90° hybrid 50. The power amplifier 12, which is an example of a second power amplifier, has the third input end and a fourth output end, the third input end connected to the second output end of the 90° hybrid 50. The power amplifiers 11 and 12 can amplify RF signals in band A or band B output from the 90° hybrid 50.

The power amplifiers 11 and 12 each have an amplifier transistor. The amplifier transistors are, for example, bipolar transistors such as heterojunction bipolar transistors (HBTs) or field-effect transistors such as MOSFETs (Metal-Oxide-Semiconductor Field Effect Transistors). Note that, in the case where the above-mentioned amplifier transistors are bipolar transistors, the input ends of the power amplifiers 11 and 12 are, for example, the base ends of the bipolar transistors, and the output ends of the power amplifiers 11 and 12 are, for example, the collector ends of the bipolar transistors. Note that, in the case where the above-mentioned amplifier transistors are field-effect transistors, the input ends of the power amplifiers 11 and 12 are, for example, the gate ends of the field-effect transistors, and the output ends of the power amplifiers 11 and 12 are, for example, the drain ends of the field-effect transistors.

The phase-shifting circuit 21, which is an example of a first phase-shifting circuit, is connected between the third output end of the power amplifier 11 and a terminal 41d of the switch circuit 41. The phase-shifting circuit 21 includes, for example, capacitors 211 and 212 and an inductor 213. The capacitor 211, which is an example of a first capacitor, is connected between the third output end and the terminal 41d. The inductor 213, which is an example of a first inductor, is connected between the path connecting the capacitor 211 and the terminal 41d and ground. The capacitor 212 is arranged in series in the path connecting the capacitor 211 and the terminal 41d. The phase-shifting circuit 21 has the configuration of a so-called high-pass filter, and sets the passband phase of the transmission signals in bands A and B to, for example, +45° (45° forward). Note that the capacitor 212 is a capacitor for DC cutting and does not contribute to phase shifting, and it is not necessary for the capacitor 212 to be included in the phase-shifting circuit 21.

The phase-shifting circuit 22, which is an example of a second phase-shifting circuit, is connected between the fourth output end of the power amplifier 12 and a terminal 41e of the switch circuit 41, and is configured to set the passband phase of the transmission signals in bands A and B to be relatively −90° (90° delayed) with respect to the phase-shifting circuit 21. The phase-shifting circuit 22 includes, for example, an inductor 221 and capacitors 222 and 223. The inductor 221, which is an example of a second inductor, is connected between the fourth output end and the terminal 41e. The capacitor 223, which is an example of a second capacitor, is connected between the path connecting the inductor 221 and the terminal 41e and ground. The capacitor 222 is arranged in series in the path connecting the inductor 221 and the terminal 41e. The phase-shifting circuit 22 has the configuration of a so-called low-pass filter, and sets the passband phase of the transmission signals in bands A and B to, for example −45° (−45° delayed). Note that the capacitor 222 is a capacitor for DC cutting and does not contribute to phase shifting, and it is not necessary for the capacitor 222 to be included in the phase-shifting circuit 22.

The switch circuit 41 is an example of a combiner circuit and has the terminals 41a, 41b, 41c, 41d. and 41e. The switch circuit 41 switches between (1) the connection between the terminal 41d and the terminal 41a and the connection between the terminal 41e and the terminal 41a (first mode), (2) the connection between the terminal 41d and the terminal 41c and the connection between the terminal 41e and the terminal 41c (second mode), and (3) the connection between the terminal 41d and the terminal 41a and the connection between the terminal 41e and the terminal 41b (third mode).

Accordingly, the switch circuit 41 (1) outputs from the terminal 41a an output signal generated by combining in phase the transmission signal in band A input from the terminal 41d and the transmission signal in band A input from the terminal 41e at the terminal 41a (first mode). Additionally, the switch circuit 41 (2) outputs from the terminal 41c an output signal generated by combining in phase the transmission signal in band B input from the terminal 41d and the transmission signal in band B input from the terminal 41e at the terminal 41c (second mode). Furthermore, the switch circuit 41 (3) outputs from the terminal 41a the transmission signal in band A input from the terminal 41d, and outputs from the terminal 41b the transmission signal in band B input from the terminal 41e (third mode).

The first mode is a mode for simultaneously transmitting the transmission signal in band A and the reception signal in band B combined in phase at the terminal 41a. The second mode is a mode for simultaneously transmitting the transmission signal in band B and the reception signal in band A combined in phase at the terminal 41c. The third mode is a mode for simultaneously transmitting the transmission signal in band A and the reception signal in band B combined in phase at the terminal 42a of the switch circuit 42.

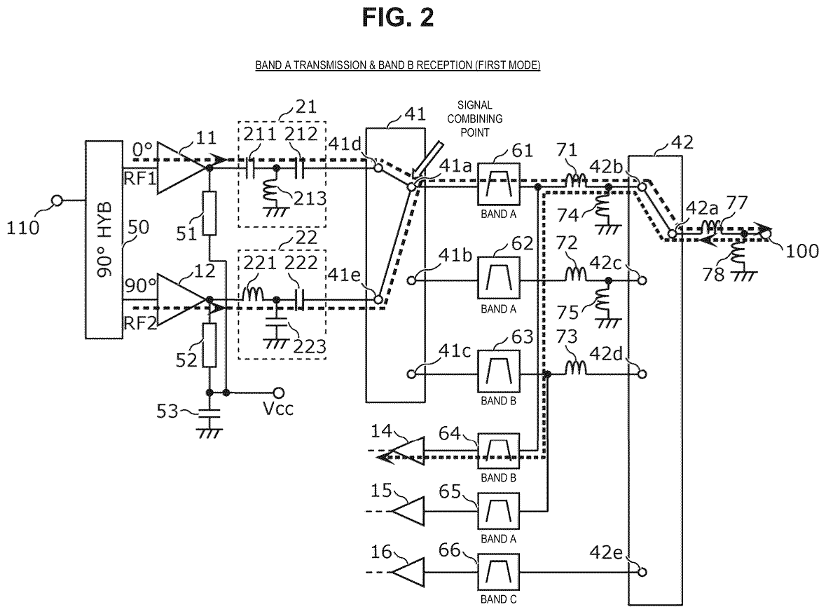

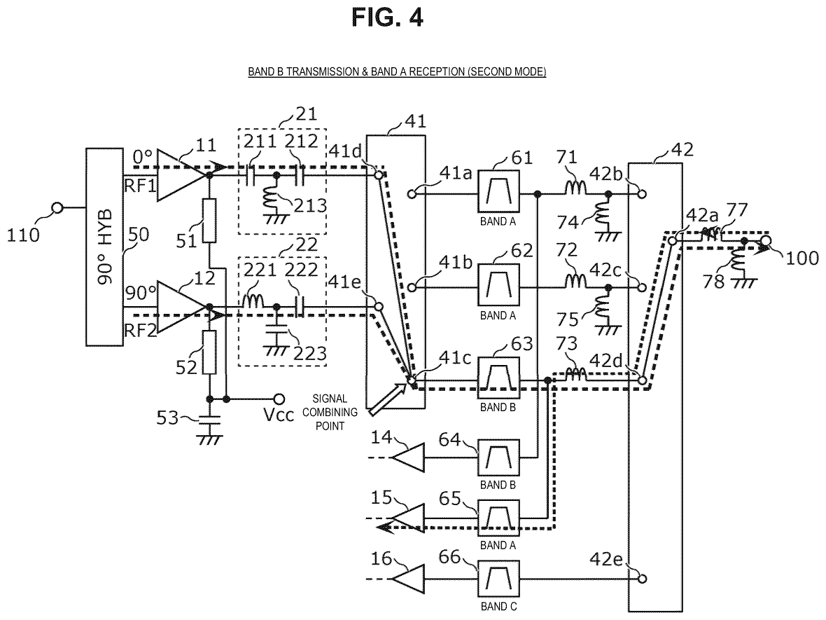

Note that, in the case where the RF circuit 1 operates in the first mode (see FIG. 2) or the second mode (see FIG. 4), the switch circuit 41 corresponds to a combiner circuit. In the case of the first mode or the second mode, the terminal 41d corresponds to a fourth input end, the terminal 41e corresponds to a fifth input end, the terminal 41a corresponds to a fifth output end, and the terminal 41c corresponds to a sixth output end. In the case of the first mode or the second mode, the terminal 41a is a signal combining point where a third sub-band signal in band A and a fourth sub-band signal in band A are combined in phase, while the terminal 41c is a signal combining point where a third sub-band signal in band B and a fourth sub-band signal in band B are combined in phase.

The phase-shifting line 51 is arranged in series between the third output end of the power amplifier 11 and the power supply voltage (Vcc) terminal, and suppresses leakage of a first RF signal, output from the power amplifier 11, to the Vcc terminal. The phase-shifting line 52 is arranged in series between the fourth output end of the power amplifier 12 and the power supply voltage (Vcc) terminal, and suppresses leakage of a second RF signal, output from the power amplifier 12, to the Vcc terminal. The capacitor 53 is connected between the Vcc terminal and ground, suppresses leakage components of the first RF signal and the second RF signal from entering the Vcc terminal, and prevents the power supply voltage from dropping to ground.

In the amplifier circuit 10 having the above-described configuration, the phase-shifting circuits 21 and 22 are configured such that the difference between a first reflection phase in the reception band of band B upon viewing the fifth output end from the third output end and a second reflection phase in the reception band of band B upon viewing the fifth output end from the fourth output end becomes 180°.

Note that the first reflection phase in the reception band of band B upon viewing the fifth output end from the third output end is defined, in the case of the first mode, as the phase change amount of the reflected signal that has been reflected at the terminal 41a and returned to the third output end, with respect to the phase of the signal in the reception band of band B output from the third output end, in the state where the terminal 41d and the terminal 41a are connected. Additionally, the second reflection phase in the reception band of band B upon viewing the fifth output end from the fourth output end is defined, in the case of the first mode, as the phase change amount of the reflected signal that has been reflected at the terminal 41a and returned to the fourth output end, with respect to the phase of the signal in the reception band of band B output from the fourth output end, in the state where the terminal 41e and the terminal 41a are connected.

Furthermore, the first reflection phase in the reception band of band B upon viewing the fifth output end from the third output end is defined, in the case of the third mode, as the phase change amount of the reflected signal that has been reflected at the terminal 42a and returned to the third output end, with respect to the phase of the signal in the reception band of band B output from the third output end, in the state where the terminal 41d and the terminal 41a are connected and the terminal 42b and the terminal 42a are connected. In addition, the second reflection phase in the reception band of band B upon viewing the fifth output end from the fourth output end is defined, in the case of the third mode, as the phase change amount of the reflected signal that has been reflected at the terminal 42a and returned to the fourth output end, with respect to the phase of the signal in the reception band of band B output from the fourth output end, in the state where the terminal 41e and the terminal 41b are connected and the terminal 42c and the terminal 42a are connected.

Accordingly, in the case of simultaneously transmitting the transmission signal in band A and the reception signal in band B, the reflection phase difference in the reception band of band B as viewed from the output ends of the two balanced power amplifiers 11 and 12 becomes 180°. This allows the reflection coefficient (P) of band B (attenuation band) in the filter 61, which has the transmission band of band A as its passband, to be increased. Therefore, this can suppress the leakage of the reception signal in band B to the two power amplifiers 11 and 12 through the filter 61, thereby improving the isolation between the transmission signal in band A and the reception signal in band B, which are transmitted simultaneously. Therefore, it is possible to provide the RF circuit 1, which is equipped with the balanced power amplifiers 11 and 12 and achieves highly efficient power combining as well as improved isolation between transmission and reception.

Note that the first reflection phase in the reception band of band B upon viewing the fifth output end from the third output end is obtained by, in the case of the first mode, measuring the reflection phase in the reception band of band B at the terminal 41a in the state where the terminal 41a and the terminal 41d are connected, the terminal 41a and the terminal 41e are disconnected, and the terminal 41a and the filter 61 are disconnected.

Additionally, the second reflection phase in the reception band of band B upon viewing the fifth output end from the fourth output end is obtained by, in the case of the first mode, measuring the reflection phase in the reception band of band B at the terminal 41a in the state where the terminal 41a and the terminal 41e are connected, the terminal 41a and the terminal 41d are disconnected, and the terminal 41a and the filter 61 are disconnected.

Furthermore, the first reflection phase in the reception band of band B upon viewing the fifth output end from the third output end is obtained by, in the case of the third mode, measuring the reflection phase in the reception band of band B at the terminal 42a in the state where the terminal 41a and the terminal 41d are connected, the terminal 41a and the terminal 41e are disconnected, the terminal 42b and the terminal 42a are connected, the terminals 42c, 42d, and 42e and the terminal 42a are disconnected, and the antenna connection terminal 100 and the antenna 2 are disconnected.

In addition, the second reflection phase in the reception band of band B upon viewing the fifth output end from the fourth output end is obtained by, in the case of the third mode, measuring the reflection phase in the reception band of band B at the terminal 42a in the state where the terminal 41b and the terminal 41e are connected, the terminal 41b and the terminal 41d are disconnected, the terminal 42c and the terminal 42a are connected, the terminals 42b, 42d, and 42e and the terminal 42a are disconnected, and the antenna connection terminal 100 and the antenna 2 are disconnected.

Furthermore, in the amplifier circuit 10 having the above-described configuration, the phase-shifting circuits 21 and 22 may be configured such that the difference between a third reflection phase in the reception band of band A upon viewing the sixth output end from the third output end and a fourth reflection phase in the reception band of band A upon viewing the sixth output end from the fourth output end becomes 180°.

Note that the third reflection phase in the reception band of band A upon viewing the sixth output end from the third output end is defined, in the case of the second mode, as the phase change amount of the reflected signal that has been reflected at the terminal 41c and returned to the third output end, with respect to the phase of the signal in the reception band of band A output from the third output end, in the state where the terminal 41d and the terminal 41c are connected. Additionally, the fourth reflection phase in the reception band of band A upon viewing the sixth output end from the fourth output end is defined, in the case of the second mode, as the phase change amount of the reflected signal that has been reflected at the terminal 41c and returned to the fourth output end, with respect to the phase of the signal in the reception band of band A output from the fourth output end, in the state where the terminal 41e and the terminal 41c are connected.

Accordingly, in the case of simultaneously transmitting the transmission signal in band B and the reception signal in band A, the reflection phase difference in the reception band of band A as viewed from the output ends of the two balanced power amplifiers 11 and 12 becomes 180°. This allows the reflection coefficient (F) of band A (attenuation band) in the filter 63, which has the transmission band of band B as its passband, to be increased. Therefore, this can suppress the leakage of the reception signal in band A to the two power amplifiers 11 and 12 through the filter 63, thereby improving the isolation between the transmission signal in band B and the reception signal in band A, which are transmitted simultaneously. Therefore, it is possible to provide the RF circuit 1, which is equipped with the balanced power amplifiers 11 and 12 and achieves highly efficient power combining as well as improved isolation between transmission and reception.

Note that the third reflection phase in the reception band of band B upon viewing the sixth output end from the third output end is obtained by, in the case of the second mode, measuring the reflection phase in the reception band of band A at the terminal 41c in the state where the terminal 41c and the terminal 41d are connected, the terminal 41c and the terminal 41e are disconnected, and the terminal 41c and the filter 63 are disconnected.

Additionally, the fourth reflection phase in the reception band of band A upon viewing the sixth output end from the fourth output end is obtained by, in the case of the second mode, measuring the reflection phase in the reception band of band A at the terminal 41c in the state where the terminal 41c and the terminal 41e are connected, the terminal 41c and the terminal 41d are disconnected, and the terminal 41c and the filter 63 are disconnected.

### 1.4 Transmission and Reception Characteristics of RF Circuit 1

FIG. 2 is a circuit state diagram illustrating the RF circuit 1 in the first mode according to the embodiment. As illustrated in the diagram, in the case of the first mode for simultaneously transmitting the transmission signal in band A and the reception signal in band B, in the switch circuit 41, the terminal 41a and the terminal 41d are connected, and the terminal 41a and the terminal 41e are connected. Additionally, in the switch circuit 42, the terminal 42a and the terminal 42b are connected.

The transmission signal in band A is separated into a first sub-band signal RF1 and a second sub-band signal RF2 by the 90° hybrid 50. These signals are then respectively input to and amplified by the power amplifiers 11 and 12 to become a first signal and a second signal. At the third output end of the power amplifier 11, the phase of the first signal is 0°, and at the fourth output end of the power amplifier 12, the phase of the second signal is 90°.

The phase of the first signal at the terminal 41a that has passed through the phase-shifting circuit 21 (the passband phase of the transmission signal in band A is +45°) is +45°, and the phase of the second signal at the terminal 41a that has passed through the phase-shifting circuit 22 (the passband phase of the transmission signal in band A is −45°) is +45°. Accordingly, the first signal and the second signal in band A are combined in phase at the terminal 41a, enabling highly efficient power combining against load fluctuations.

Furthermore, due to the phase-shifting circuits 21 and 22, the difference between the first reflection phase (+45°×2=90°) in the reception band of band B upon viewing the terminal 41a from the third output end and the second reflection phase (−45°×2=−90°) in the reception band of band B upon viewing the terminal 41a from the fourth output end is 180°.

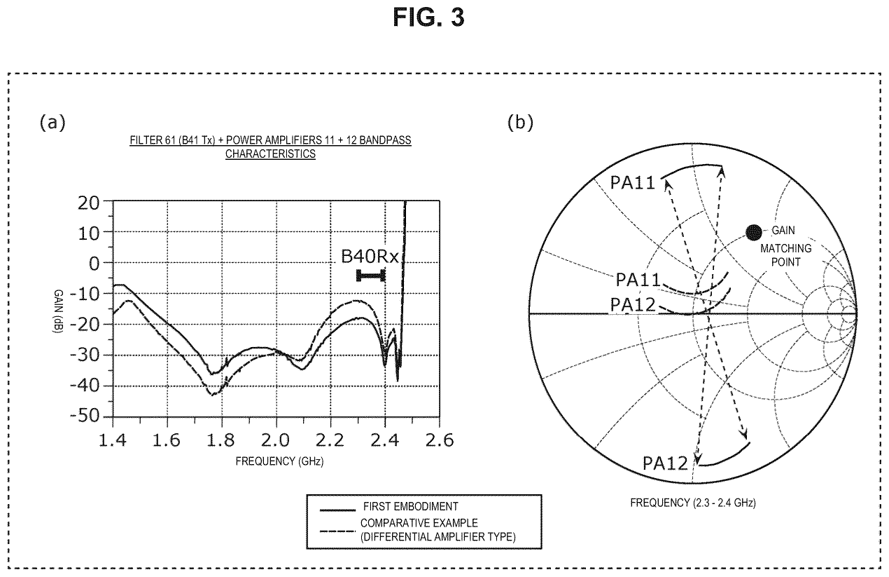

FIG. 3 includes a Smith chart representing the transmission bandpass characteristics as well as the impedance in the reception band of an RF circuit according to a first embodiment and a comparative example. The RF circuit according to the first embodiment has the same configuration and characteristics as the RF circuit 1 according to the embodiment, with band A being band B41 for 4G-LTE (TDD: 2496-2690 MHz) and band B being band B40 for 4G-LTE (TDD: 2300-2400 MHz). In addition, the RF circuit according to the comparative example has the same circuit configuration as the RF circuit 1 according to the embodiment, but the phase-shifting circuits 21 and 22 do not have the characteristic that they are “configured such that the difference between the first reflection phase in the reception band of band B upon viewing the fifth output end from the third output end and the second reflection phase in the reception band of band B upon viewing the fifth output end from the fourth output end becomes 1800”.

The difference between the first reflection phase in the band B40 range at the third output end of the power amplifier 11 (PA11) and the second reflection phase in the band B40 range at the fourth output end of the power amplifier 12 (PA12) is 180°. Thus, as illustrated in part (b) of FIG. 3, the reflection coefficient (P) of the band B40 range (2300-2400 MHz) increases, causing the output impedance of the power amplifier 11 (PA11) and the output impedance of the power amplifier 12 (PA12) to undergo a phase inversion. The band B40 range moves away from the gain matching point, allowing for reduced gain across the entire B40 range.

This greatly improves the attenuation of band B40 (reception band Rx) in the bandpass characteristics of the circuit where the power amplifiers 11 and 12 are combined with the filter 61, as illustrated in part (a) of FIG. 3. Therefore, this can suppress the leakage of the reception signal in band B to the two power amplifiers 11 and 12 through the filter 61, thereby improving the isolation between the transmission signal in band A and the reception signal in band B, which are transmitted simultaneously. Therefore, it is possible to provide the RF circuit 1, which is equipped with the balanced power amplifiers 11 and 12 and achieves highly efficient power combining as well as improved isolation between transmission and reception.

FIG. 4 is a circuit state diagram illustrating the RF circuit 1 in the second mode according to the embodiment. As illustrated in the diagram, in the case of the second mode for simultaneously transmitting the transmission signal in band B and the reception signal in band A, in the switch circuit 41, the terminal 41c and the terminal 41d are connected, and the terminal 41c and the terminal 41e are connected. Additionally, in the switch circuit 42, the terminal 42a and the terminal 42d are connected.

The transmission signal in band B is separated into a first sub-band signal RF1 and a second sub-band signal RF2 by the 90° hybrid 50. These signals are then respectively input to and amplified by the power amplifiers 11 and 12 to become a first signal and a second signal. At the third output end of the power amplifier 11, the phase of the first signal is 0°, and at the fourth output end of the power amplifier 12, the phase of the second signal is 90°.

The phase of the first signal at the terminal 41c that has passed through the phase-shifting circuit 21 (the passband phase of the transmission signal in band B is +45°) is +45°, and the phase of the second signal at the terminal 41c that has passed through the phase-shifting circuit 22 (the passband phase of the transmission signal in band B is −45°) is +45°. Accordingly, the first signal and the second signal in band B are combined in phase at the terminal 41c, enabling highly efficient power combining against load fluctuations.

Furthermore, due to the phase-shifting circuits 21 and 22, the difference between the third reflection phase (+45°×2=90°) in the reception band of band A upon viewing the terminal 41c from the third output end and the fourth reflection phase (−45°×2=−90°) in the reception band of band A upon viewing the terminal 41c from the fourth output end is 180°.

Accordingly, the reflection coefficient (F) of the reception band of band A increases, causing the output impedance of the power amplifier 11 and the output impedance of the power amplifier 12 to undergo a phase inversion. The reception band of band A moves away from the gain matching point, allowing for reduced gain across the entire reception band of band A.

This greatly improves the attenuation in the reception band of band A in the bandpass characteristics of the circuit where the power amplifiers 11 and 12 are combined with the filter 63. Therefore, this can suppress the leakage of the reception signal in band A to the two power amplifiers 11 and 12 through the filter 63, thereby improving the isolation between the transmission signal in band B and the reception signal in band A, which are transmitted simultaneously. Therefore, it is possible to provide the RF circuit 1, which is equipped with the balanced power amplifiers 11 and 12 and achieves highly efficient power combining as well as improved isolation between transmission and reception.

FIG. 5 is a circuit state diagram illustrating the RF circuit 1 in the third mode according to the embodiment. As illustrated in the diagram, in the case of the third mode for simultaneously transmitting the transmission signal in band A and the reception signal in band B, in the switch circuit 41, the terminal 41a and the terminal 41d are connected, and the terminal 41b and the terminal 41e are connected. Additionally, in the switch circuit 42, the terminal 42a and the terminal 42b are connected, and the terminal 42a and the terminal 42c are connected.

The transmission signal in band A is separated into a first sub-band signal RF1 and a second sub-band signal RF2 by the 90° hybrid 50. These signals are then respectively input to and amplified by the power amplifiers 11 and 12 to become a first signal and a second signal. At the third output end of the power amplifier 11, the phase of the first signal is 0°, and at the fourth output end of the power amplifier 12, the phase of the second signal is 90°.

The phase of the first signal at the terminal 41a that has passed through the phase-shifting circuit 21 (the passband phase of the transmission signal in band A is +45°) is +45°, and the phase of the second signal at the terminal 41b that has passed through the phase-shifting circuit 22 (the passband phase of the transmission signal in band A is −45°) is +45°. In addition, because the filter 61 through which the first signal passes and the filter 62 through which the second signal passes have the same passband and characteristics, the passband phases of the filter 61 and the filter 62 are equal. Accordingly, the first signal and the second signal in band A are combined in phase at the terminal 42a, enabling highly efficient power combining against load fluctuations.

Furthermore, due to the phase-shifting circuits 21 and 22, the difference between the first reflection phase (+45°×2=90°) in the reception band of band B upon viewing the terminal 42a from the third output end and the second reflection phase (−45°×2=−90°) in the reception band of band B upon viewing the terminal 42a from the fourth output end is 180°.

Accordingly, the reflection coefficient (F) of the reception band of band B increases, causing the output impedance of the power amplifier 11 and the output impedance of the power amplifier 12 to undergo a phase inversion. The reception band of band B moves away from the gain matching point, allowing for reduced gain across the entire reception band of band B.

This greatly improves the attenuation in the reception band of band B in the bandpass characteristics of the circuit where the power amplifiers 11 and 12 are combined with the filters 61 and 62. Therefore, this can suppress the leakage of the reception signal in band B to the two power amplifiers 11 and 12 through the filter 61 or 62, thereby improving the isolation between the transmission signal in band A and the reception signal in band B, which are transmitted simultaneously. Therefore, it is possible to provide the RF circuit 1, which is equipped with the balanced power amplifiers 11 and 12 and achieves highly efficient power combining as well as improved isolation between transmission and reception.

Note that, in the first mode, the transmission signal in band A passes through the filter 61, whereas, in the third mode, the transmission signal in band A passes through the filters 61 and 62. Accordingly, in the case of simultaneous transmission of transmission in band A and reception in band B, the first mode can reduce the number of filters used, while the third mode can ease the electric power handling capability of the filters, allowing for miniaturization of a single filter.

Furthermore, in the third mode, the switch circuit 42 uses a combiner circuit that combines balanced signals also as an antenna switch circuit, allowing for the miniaturization of the RF circuit 1.

### 2 Configuration of Amplifier Circuit, RF Circuit, and Communication Device According to First Modification

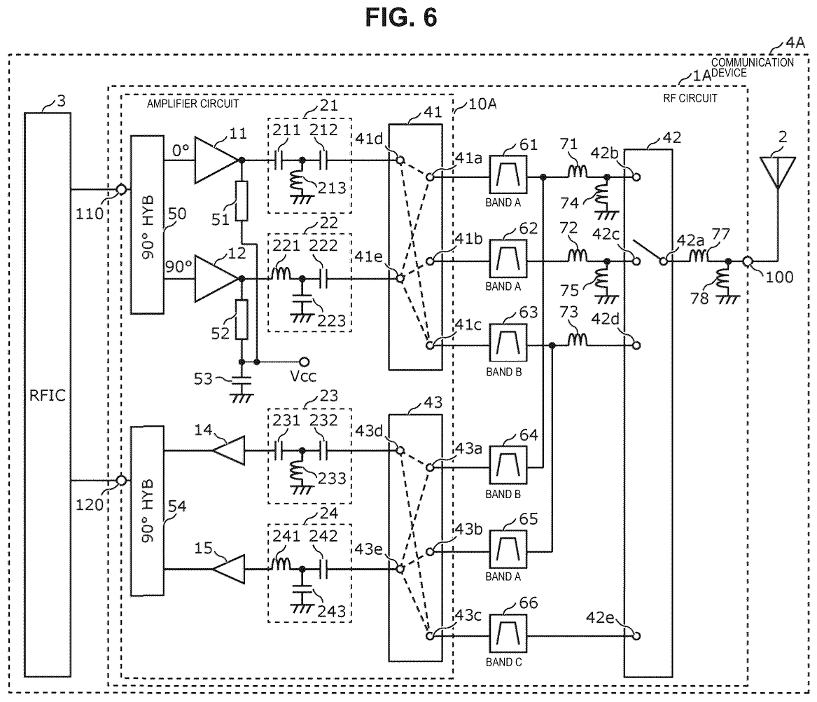

While the amplifier circuit 10 according to the embodiment has the function of adjusting the reflection phase of the transmission path, an amplifier circuit 10A according to a first modification has the function of adjusting the reflection phase of the reception path. FIG. 6 is a circuit configuration diagram of the amplifier circuit 10A, an RF circuit 1A, and a communication device 4A according to the first modification of the embodiment. As illustrated in the diagram, the communication device 4A according to the present modification includes the RF circuit 1A, the antenna 2, and the RFIC 3. The communication device 4A according to the present modification differs from the communication device 4 according to the embodiment in the configuration of the RF circuit 1A. Therefore, the configuration of the RF circuit 1A according to the present modification will be described below.

The RF circuit 1A includes the amplifier circuit 10A, the filters 61 to 66, the switch circuit 42, the inductors 71 to 78, and the antenna connection terminal 100. The RF circuit 1A according to the present modification mainly differs from the RF circuit 1 according to the embodiment in the configuration of the amplifier circuit 10A. Hereinafter, the RF circuit 1A according to the present modification will be described, mainly focusing on different configurations while omitting the description of the same configurations as the RF circuit 1 according to the embodiment.

The amplifier circuit 10A is a circuit that amplifies transmission signals in band A and band B, input from the RF input terminal 110, amplifies reception signals in band A and band B, input from the antenna connection terminal 100, and outputs them from an RF output terminal 120.

The filter 61, which is an example of a second filter, is connected between the switch circuit 41 and the antenna connection terminal 100 and has a passband containing the transmission band of band A (second band). One end of the filter 61 is connected to the path connecting the antenna connection terminal 100 and the filter 64, and the other end is connected to the switch circuit 41.

The filter 62 is connected between the phase-shifting circuit 22 and the switch circuit 42 and has a passband containing the transmission band of band A (second band).

The filter 63 is connected between the switch circuit 41 and the antenna connection terminal 100 and has a passband containing the transmission band of band B (first band). One end of the filter 63 is connected to the path connecting the antenna connection terminal 100 and the filter 65, and the other end is connected to the switch circuit 41.

The filter 64, which is an example of a first filter, is connected between a switch circuit 43 and the antenna connection terminal 100 and has a passband containing the reception band of band B (first band). Specifically, one end of the filter 64 is connected to a terminal 43a of the switch circuit 43, and the other end of the filter 64 is connected to the antenna connection terminal 100 with the inductors 71 and 77 and the switch circuit 42 interposed therebetween.

The filter 65, which is an example of a third filter, is connected between the switch circuit 43 and the antenna connection terminal 100 and has a passband containing the reception band of band A (second band). Specifically, one end of the filter 65 is connected to a terminal 43b of the switch circuit 43, and the other end of the filter 65 is connected to the antenna connection terminal 100 with the inductors 73 and 77 and the switch circuit 42 interposed therebetween.

The filter 66 has a passband containing the reception band of band C. One end of the filter 66 is connected to the terminal 42e of the switch circuit 42, and the other end is connected to a terminal 43c of the switch circuit 43.

Band A (second band) and band B (first band) are a combination of bands allowing simultaneous transmission. Note that each of band A (second band) and band B (first band) may be a band using time-division duplexing (TDD). In this case, the filters 61 to 65 may have the same passband.

Band A is, for example, band B41 for 4G-LTE or band n41 for 5G-NR, while band B is, for example, band B40 for 4G-LTE or band n40 for 5G-NR.

The switch circuit 42, which is an example of an antenna switch, has the terminals 42a, 42b, 42c, 42d, and 42e. The terminal 42a is connected to the antenna connection terminal 100 with the inductor 77 interposed therebetween; the terminal 42b is connected to the filters 61 and 64 with the inductor 71 interposed therebetween; the terminal 42c is connected to the filter 62 with the inductor 72 interposed therebetween; the terminal 42d is connected to the filters 63 and 65 with the inductor 73 interposed therebetween; and the terminal 42e is connected to the filter 66.

According to the above-mentioned circuit configuration, the RF circuit 1A can perform simultaneous transmission of the transmission signal in band A and the reception signal in band B, as well as simultaneous transmission of the transmission signal in band B and the reception signal in band A.

Note that the RF circuit 1A according to the present modification may have at least the amplifier circuit 10A and the filters 61 and 64 in the circuit configuration illustrated in FIG. 6.

Next, the circuit configuration of the amplifier circuit 10A will be described in detail.

As illustrated in FIG. 6, the amplifier circuit 10A includes the power amplifiers 11 and 12, low-noise amplifiers 14 and 15, phase-shifting circuits 21, 22, 23, and 24, switch circuits 41 and 43, 90° hybrids 50 and 54, phase-shifting lines 51 and 52, capacitor 53, RF input terminal 110, and RF output terminal 120. The amplifier circuit 10A according to the present modification differs from the amplifier circuit 10 according to the embodiment in the configuration of the reception circuit. Hereinafter, the amplifier circuit 10A according to the present modification will be described, mainly focusing on the reception circuit, which is a different configuration, while omitting the description of the transmission circuit, which is the same configuration as the amplifier circuit 10 according to the embodiment.

The RF output terminal 120 is connected to the RFIC 3. Note that the RF output terminal 120 may be a metal conductor such as a metal electrode and a metal bump, or may be a single point (node) on the metal wiring.

The 90° hybrid 54, which is an example of a combiner, has a first output end, a first input end, and a second input end, the first output end connected to the RF output terminal 120, the first input end connected to a second output end of the low-noise amplifier 14, and the second input end connected to a third output end of the low-noise amplifier 15. The 90° hybrid 54 is configured to combine a first signal in the reception band of band A or band B, input to the first input end, and a second signal in the reception band of band A or band B, input to the second input end, where the second signal is relatively +90° with respect to the first signal, and output the combined signal from the first output end.

Note that, instead of the 90° hybrid 54, a phase-shifting circuit having other circuit configuration may be arranged.

The low-noise amplifier 14, which is an example of a first low-noise amplifier, has a second output end and a third input end, the second output end connected to the first input end of the 90° hybrid 54. The low-noise amplifier 15, which is an example of a second low-noise amplifier, has a third output end and a fourth input end, the third output end connected to the second input end of the 90° hybrid 54.

The low-noise amplifiers 14 and 15 each have an amplifier transistor. The amplifier transistors are, for example, bipolar transistors such as HBTs or field-effect transistors such as MOSFETs. Note that, in the case where the amplifier transistors are bipolar transistors, the input ends of the low-noise amplifiers 14 and 15 are, for example, the base ends of the bipolar transistors, and the output ends of the low-noise amplifiers 14 and 15 are, for example, the collector ends of the bipolar transistors. Note that, in the case where the amplifier transistors are field-effect transistors, the input ends of the low-noise amplifiers 14 and 15 are, for example, the gate ends of the field-effect transistors, and the output ends of the low-noise amplifiers 14 and 15 are, for example, the drain ends of the field-effect transistors.

The phase-shifting circuit 23, which is an example of a first phase-shifting circuit, is connected between the third input end of the low-noise amplifier 14 and a terminal 43d of the switch circuit 43. The phase-shifting circuit 23 includes, for example, capacitors 231 and 232 and an inductor 233. The capacitor 231 is connected between the third input end and the terminal 43d. The inductor 233 is connected between the path connecting the capacitor 231 and the terminal 43d and ground. The capacitor 232 is arranged in series in the path connecting the capacitor 231 and the terminal 43d. The phase-shifting circuit 23 has the configuration of a so-called high-pass filter, and sets the passband phase of the reception signals in bands A and B to, for example, +45° (45° forward). Note that the capacitor 232 is a capacitor for DC cutting and does not contribute to phase shifting, and it is not necessary for the capacitor 232 to be included in the phase-shifting circuit 23.

The phase-shifting circuit 24, which is an example of a second phase-shifting circuit, is connected between the fourth input end of the low-noise amplifier 15 and a terminal 43e of the switch circuit 43, and is configured to set the passband phase of the reception signals in bands A and B to be relatively −90° (90° delayed) with respect to the phase-shifting circuit 23. The phase-shifting circuit 24 includes, for example, an inductor 241 and capacitors 242 and 243. The inductor 241 is connected between the fourth input end and the terminal 43e. The capacitor 243 is connected between the path connecting the inductor 241 and the terminal 43e and ground. The capacitor 242 is arranged in series in the path connecting the inductor 241 and the terminal 43e. The phase-shifting circuit 24 has the configuration of a so-called low-pass filter, and sets the passband phase of the reception signals in bands A and B to, for example −45° (−45° delayed). Note that the capacitor 242 is a capacitor for DC cutting and does not contribute to phase shifting, and it is not necessary for the capacitor 242 to be included in the phase-shifting circuit 24.

The switch circuit 43, which is an example of a splitter circuit, has the terminals 43a, 43b, 43c, 43d, and 43e, and switches between (1) the connection between the terminal 43d and the terminal 43a and the connection between the terminal 43e and the terminal 43a (first mode), and (2) the connection between the terminal 43d and the terminal 43b and the connection between the terminal 43e and the terminal 43b (second mode).

Accordingly, the switch circuit 43 (1) distributes the power of the reception signal in band B, which is input to the terminal 43a, to the terminal 43d and the terminal 43e (first mode). Additionally, the switch circuit 43 (2) distributes the power of the reception signal in band A, which is input to the terminal 43b, to the terminal 43d and the terminal 43e (second mode).

The first mode is a mode for simultaneously transmitting the transmission signal in band A, combined in-phase at the terminal 41a, and the reception signal in band B, power-distributed at the terminal 43a. The second mode is a mode for simultaneously transmitting the transmission signal in band B, combined in-phase at the terminal 41c, and the reception signal in band A, power-distributed at the terminal 43b.

Note that, in the case where the RF circuit 1A operates in the first mode or the second mode, the switch circuit 41 corresponds to a combiner circuit, and the switch circuit 43 corresponds to a splitter circuit. In the case of the first mode or the second mode, the terminal 43d corresponds to a fourth output end, the terminal 43e corresponds to a fifth output end, the terminal 43a corresponds to a fifth input end, and the terminal 43b corresponds to a sixth input end. In the case of the first mode or the second mode, the terminal 43a is a signal distribution point at which the power of the reception signal in band B is distributed to a first signal in band B and a second signal in band B, and the terminal 43b is a signal distribution point at which the power of the reception signal in band A is distributed to a first signal in band A and a second signal in band A.

In the amplifier circuit 10A having the above-described configuration, the phase-shifting circuits 23 and 24 are configured such that the difference between a first reflection phase in the transmission band of band A upon viewing the fifth input end from the third input end and a second reflection phase in the transmission band of band A upon viewing the fifth input end from the fourth input end becomes 180°.

Accordingly, in the case of simultaneously transmitting the reception signal in band B and the transmission signal in band A, the reflection phase difference in the transmission band of band A as viewed from the input ends of the two balanced low-noise amplifiers 14 and 15 becomes 180°. This allows the reflection coefficient (P) of band A (attenuation band) in the filter 64, which has the reception band of band B as its passband, to be increased. Therefore, this can suppress the leakage of the transmission signal in band A to the two low-noise amplifiers 14 and 15 through the filter 64, thereby improving the isolation between the transmission signal in band A and the reception signal in band B, which are transmitted simultaneously, as well as suppressing the degradation of the reception sensitivity of band B. Therefore, it is possible to provide the RF circuit 1A, which is equipped with the balanced low-noise amplifiers 14 and 15 and achieves highly efficient power combining as well as improved isolation between transmission and reception.

Note that the first reflection phase in the transmission band of band A upon viewing the fifth input end from the third input end is obtained by, in the case of the first mode, measuring the reflection phase in the transmission band of band A at the terminal 43a in the state where the terminal 43a and the terminal 43d are connected, the terminal 43a and the terminal 43e are disconnected, and the terminal 43a and the filter 64 are disconnected.

Additionally, the second reflection phase in the transmission band of band A upon viewing the fifth input end from the fourth input end is obtained by, in the case of the first mode, measuring the reflection phase in the transmission band of band A at the terminal 43a in the state where the terminal 43a and the terminal 43e are connected, the terminal 43a and the terminal 43d are disconnected, and the terminal 43a and the filter 64 are disconnected.

Furthermore, in the amplifier circuit 10A having the above-described configuration, the phase-shifting circuits 23 and 24 may be configured such that the difference between a third reflection phase in the transmission band of band B upon viewing the sixth input end from the third input end and a fourth reflection phase in the transmission band of band B upon viewing the sixth input end from the fourth input end becomes 180°.

Accordingly, in the case of simultaneously transmitting the reception signal in band A and the transmission signal in band B, the reflection phase difference in the transmission band of band B as viewed from the input ends of the two balanced low-noise amplifiers 14 and 15 becomes 180°. This allows the reflection coefficient (F) of band B (attenuation band) in the filter 65, which has the reception band of band A as its passband, to be increased. Therefore, this can suppress the leakage of the transmission signal in band B to the two low-noise amplifiers 14 and 15 through the filter 65, thereby improving the isolation between the reception signal in band A and the transmission signal in band B, which are transmitted simultaneously, as well as suppressing the degradation of the reception sensitivity of band A. Therefore, it is possible to provide the RF circuit 1A, which is equipped with the balanced low-noise amplifiers 14 and 15 and achieves highly efficient power combining as well as improved isolation between transmission and reception.

Note that the third reflection phase in the transmission band of band B upon viewing the sixth input end from the third input end is obtained by, in the case of the second mode, measuring the reflection phase in the transmission band of band B at the terminal 43b in the state where the terminal 43b and the terminal 43d are connected, the terminal 43b and the terminal 43e are disconnected, and the terminal 43b and the filter 65 are disconnected.

Additionally, the fourth reflection phase in the transmission band of band B upon viewing the sixth input end from the fourth input end is obtained by, in the case of the second mode, measuring the reflection phase in the transmission band of band B at the terminal 43b in the state where the terminal 43b and the terminal 43e are connected, the terminal 43b and the terminal 43d are disconnected, and the terminal 43b and the filter 65 are disconnected.

### 3 Configuration of Amplifier Circuit and RF Circuit According to Second Modification

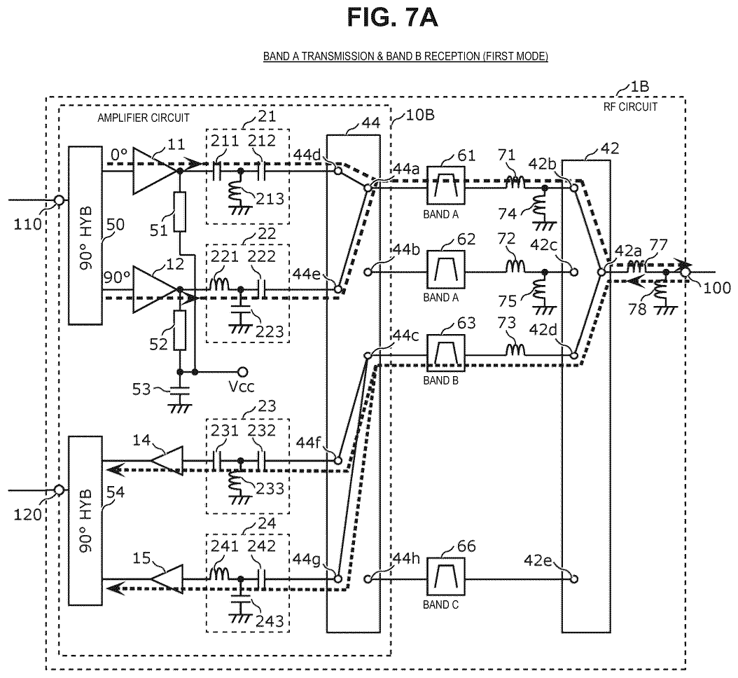

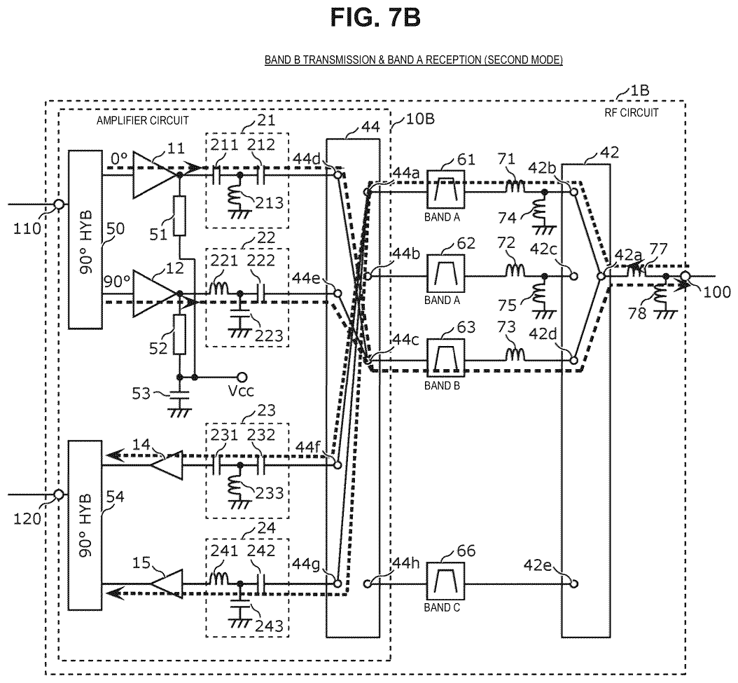

In a second modification, the configuration has fewer filters compared to the RF circuit 1A according to the first modification. FIG. 7A is a circuit state diagram illustrating an RF circuit 1B in the first mode according to the second modification of the embodiment. FIG. 7B is a circuit state diagram illustrating the RF circuit 1B in the second mode according to the second modification of the embodiment.

As illustrated in FIGS. 7A and 7B, the RF circuit 1B according to the present modification includes an amplifier circuit 10B, the filters 61 to 63 and 66, the switch circuit 42, the inductors 71 to 78, and the antenna connection terminal 100. The RF circuit 1B according to the present modification mainly differs from the RF circuit 1A according to the first modification in that the filters 61 and 63 are used for both transmission and reception. Hereinafter, the RF circuit 1B according to the present modification will be described, mainly focusing on different configurations while omitting the description of the same configurations as the RF circuit 1A according to the first modification.

Band A (second band) and band B (first band) are a combination of bands allowing simultaneous transmission. Each of band A (second band) and band B (first band) is a band using time-division duplexing (TDD). Therefore, the transmission band and the reception band of band A are the same, and the transmission band and the reception band of band B are the same.

The filter 61, which is an example of a second filter, is connected between a terminal 44a of a switch circuit 44 and the antenna connection terminal 100 and has a passband containing band A (second band).

The filter 62 is connected between the phase-shifting circuit 22 and the switch circuit 42 and has a passband containing band A (second band).

The filter 63, which is an example of a first filter, is connected between a terminal 44c of the switch circuit 44 and the antenna connection terminal 100 and has a passband containing band B (first band).

The filter 66 has a passband containing the reception band of band C. One end of the filter 66 is connected to the terminal 42e of the switch circuit 42, and the other end is connected to a terminal 44h of the switch circuit 44.

The switch circuit 42, which is an example of an antenna switch, has the terminals 42a, 42b, 42c, 42d, and 42e. The terminal 42a is connected to the antenna connection terminal 100 with the inductor 77 interposed therebetween; the terminal 42b is connected to the filter 61 with the inductor 71 interposed therebetween; the terminal 42c is connected to the filter 62 with the inductor 72 interposed therebetween; the terminal 42d is connected to the filter 63 with the inductor 73 interposed therebetween; and the terminal 42e is connected to the filter 66.

As illustrated in FIGS. 7A and 7B, the amplifier circuit 10B includes the power amplifiers 11 and 12, low-noise amplifiers 14 and 15, phase-shifting circuits 21, 22, 23 and 24, switch circuit 44, 90° hybrids 50 and 54, phase-shifting lines 51 and 52, capacitor 53, RF input terminal 110, and RF output terminal 120. The amplifier circuit 10B according to the present modification mainly differs from the amplifier circuit 10A according to the first modification in the configuration of the switch circuit 44. Hereinafter, the amplifier circuit 10B according to the present modification will be described, mainly focusing on different configurations while omitting the description of the same configurations as the amplifier circuit 10A according to the first modification.

The switch circuit 44, which is an example of a combiner circuit and a splitter circuit, has terminals 44a, 44b, 44c, 44d, 44e, 44f, 44g, and 44h and switches between (1) the connection between the terminal 44a and the terminal 44d, the connection between the terminal 44a and the terminal 44e, the connection between the terminal 44c and the terminal 44f, and the connection between the terminal 44c and the terminal 44g (first mode), and (2) the connection between the terminal 44c and the terminal 44d, the connection between the terminal 44c and the terminal 44e, the connection between the terminal 44a and the terminal 44f, and the connection between the terminal 44a and the terminal 44g (second mode).

The terminal 44a is connected to the filter 61; the terminal 44b is connected to the filter 62; the terminal 44c is connected to the filter 63; the terminal 44d is connected to the phase-shifting circuit 21; the terminal 44e is connected to the phase-shifting circuit 22; the terminal 44f is connected to the phase-shifting circuit 23; the terminal 44g is connected to the phase-shifting circuit 24; and the terminal 44h is connected to the filter 66.

Accordingly, the switch circuit 44, as illustrated in FIG. 7A, (1) outputs from the terminal 44a an output signal generated by combining in phase the transmission signal in band A input from the terminal 44d and the transmission signal in band A input from the terminal 44e at the terminal 44a; and, at the same time, distributes the power of the reception signal in band B input to the terminal 44c and outputs them from the terminal 44f and terminal 44g. Additionally, the switch circuit 44, as illustrated in FIG. 7B, (2) outputs from the terminal 44c an output signal generated by combining in phase the transmission signal in band A input from the terminal 44d and the transmission signal in band B input from the terminal 44e at the terminal 44c; and, at the same time, distributes the power of the reception signal in band A input to the terminal 44a and outputs them from the terminal 44f and terminal 44g.

Accordingly, in the case of simultaneously transmitting the transmission signal in band A and the reception signal in band B, the reflection phase difference of band B as viewed from the output ends of the two balanced power amplifiers 11 and 12 becomes 180°. This allows the reflection coefficient (P) of band B (attenuation band) in the filter 61, which has band A as its passband, to be increased. Therefore, this can suppress the leakage of the reception signal in band B to the two power amplifiers 11 and 12 through the filter 61. Additionally, the reflection phase difference of band A as viewed from the input ends of the two balanced low-noise amplifiers 14 and 15 becomes 180°. This allows the reflection coefficient (P) of band A (attenuation band) in the filter 63, which has band B as its passband, to be increased. Therefore, this can suppress the leakage of the transmission signal in band A to the two low-noise amplifiers 14 and 15 through the filter 63. This can improve the isolation between the transmission signal in band A and the reception signal in band B, which are transmitted simultaneously.

Additionally, in the case of simultaneously transmitting the transmission signal in band B and the reception signal in band A, the reflection phase difference of band A as viewed from the output ends of the two balanced power amplifiers 11 and 12 becomes 180°. This allows the reflection coefficient (P) of band A (attenuation band) in the filter 63, which has band B as its passband, to be increased. Therefore, this can suppress the leakage of the reception signal in band A to the two power amplifiers 11 and 12 through the filter 63. Additionally, the reflection phase difference of band A as viewed from the input ends of the two balanced low-noise amplifiers 14 and 15 becomes 180°. This allows the reflection coefficient (F) of band B (attenuation band) in the filter 61, which has band A as its passband, to be increased. Therefore, this can suppress the leakage of the transmission signal in band B to the two low-noise amplifiers 14 and 15 through the filter 61. This can improve the isolation between the transmission signal in band B and the reception signal in band A, which are transmitted simultaneously. Therefore, it is possible to achieve highly efficient power combining and distribution, as well as improved isolation between transmission and reception, by having the balanced power amplifiers 11 and 12, as well as the balanced low-noise amplifiers 14 and 15.

Furthermore, the transmission signal and the reception signal in band A pass through the same filter 61, and the transmission signal and the reception signal in band B pass through the same filter 63. Therefore, the RF circuit 1B can be miniaturized.

### 4 Arrangement of Components of RF Circuit According to Second Modification

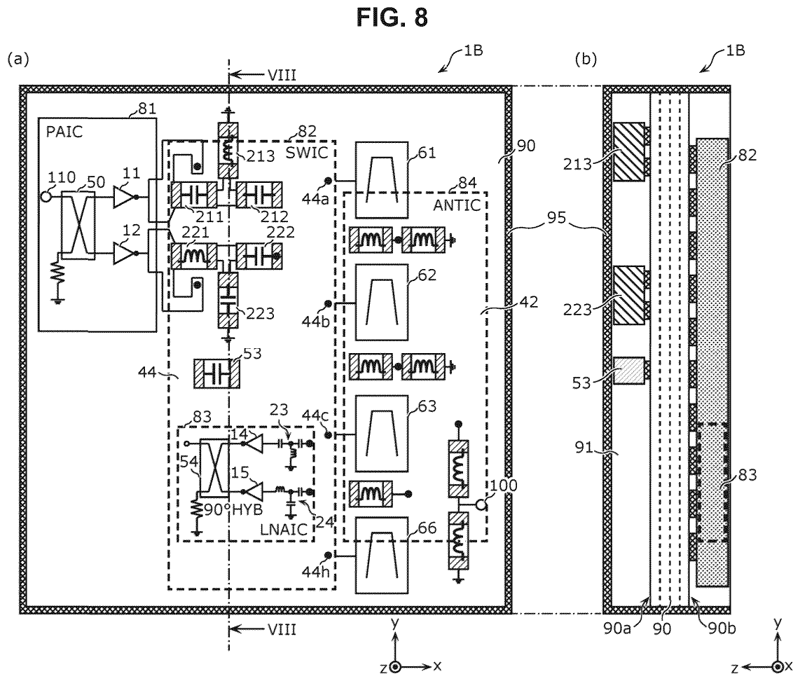

Next, the arrangement of components of the RF circuit 1B according to the second modification will be described. FIG. 8 includes a plan view and a cross-sectional view of the RF circuit 1B according to the second modification of the embodiment. Part (a) of FIG. 8 illustrates the arrangement of circuit components (depicted by solid lines) in the case where a main surface 90a of a mounting substrate 90 is viewed from the positive side of the z-axis, and the arrangement of circuit components (depicted by dashed lines) in the case where a main surface 90b of the mounting substrate 90 is seen in a transparent view from the positive side of the Z-axis. Additionally, part (b) of FIG. 8 illustrates a cross-sectional view taken along the VIII-VIII line in part (a) of FIG. 8. Note that, in FIG. 8, the illustration of the mounting substrate 90 and the wiring that connects each circuit component is partially omitted.

The RF circuit 1B illustrated in FIG. 8 has the mounting substrate 90, a resin member 91, and a shield electrode layer 95 in addition to the RF circuit 1B illustrated in FIGS. 7A and 7B.

The mounting substrate 90 is a substrate that has the main surfaces 90a and 90b facing each other, and that mounts circuit components constituting the RF circuit 1B. As the mounting substrate 90, for example, a low temperature co-fired ceramics (LTCC) substrate, a high temperature co-fired ceramics (HTCC) substrate, a substrate with built-in components, a substrate having a redistribution layer (RDL), or a printed substrate, which has a multilayer structure of multiple dielectric layers, is used.

The resin member 91 is arranged on the main surface 90a and covers part of the circuit components and the main surface 90a. The resin member 91 has the function of ensuring the reliability, such as mechanical strength and moisture resistance, of the circuit components.

The shield electrode layer 95 covers the front and lateral sides of the resin member 91 and is set to a ground potential. This improves the electromagnetic field shielding function against the external circuit.

Note that the resin member 91 and the shield electrode layer 95 are not essential components of the RF circuit 1B.

As illustrated in FIG. 8, the main surface 90a is provided with the power amplifiers 11 and 12, phase-shifting circuits 21 and 22, 90° hybrid 50, filters 61 to 63 and 66, RF input terminal 110, and antenna connection terminal 100. Additionally, the main surface 90b is provided with the low-noise amplifiers 14 and 15, phase-shifting circuits 23 and 24, switch circuits 42 and 44, and 90° hybrid 54.

Accordingly, the circuit components constituting the RF circuit 1B are arranged separately on the main surfaces 90a and 90b of the mounting substrate 90, thereby miniaturizing the RF circuit 1B.

The power amplifiers 11 and 12 and the 90° hybrid 50 are included in a semiconductor integrated circuit (IC) 81. The low-noise amplifiers 14 and 15, the 90° hybrid 54, and the phase-shifting circuits 23 and 24 are included in a semiconductor IC 83. The switch circuit 44 is included in a semiconductor IC 82. The switch circuit 42 is included in a semiconductor IC 84. The semiconductor IC 81 is arranged on the main surface 90a, and the semiconductor ICs 82 to 84 are arranged on the main surface 90b. Note that the semiconductor IC 83 may be formed within the semiconductor IC 82.

The semiconductor ICs 81 to 84 are configured, for example, using CMOS (Complementary Metal Oxide Semiconductor), and specifically may be manufactured using a SOI (Silicon on Insulator) process. Furthermore, the semiconductor ICs 81 to 84 may be made of at least one of GaAs, SiGe, and GaN. Note that the semiconductor materials of the semiconductor ICs 81 to 84 are not limited to the materials described above.

Accordingly, the RF circuit 1B can be miniaturized.

Each of the filters 61 to 63 overlaps with the semiconductor IC 84 upon the mounting substrate 90 is viewed in plan. Accordingly, the wiring connecting the filters 61 to 63 and the switch circuit 42 can be shortened, thereby reducing the signal transmission losses in bands A and B.

Note that at least one of the phase-shifting circuit 21 (capacitors 211 and 212 and inductor 213) and the phase-shifting circuit 22 (inductor 221 and capacitors 222 and 223) may be included in the semiconductor IC 82. Accordingly, part of the phase-shifting circuits 21 and 22 can be included in the semiconductor IC 82 in which the switch circuit 44 is formed, thereby miniaturizing the RF circuit 1B.

Note that the arrangement of components of the RF circuit 1B according to the present modification is also applicable to the arrangement of components of the RF circuit 1 according to the embodiment. That is, the RF circuit 1 has the mounting substrate 90, and the power amplifiers 11 and 12, phase-shifting circuits 21 and 22, 90° hybrid 50, filters 61 to 66, RF input terminal 110, and antenna connection terminal 100 are arranged on the main surface 90a. Additionally, the low-noise amplifiers 14 to 16 and the switch circuits 41 and 42 are arranged on the main surface 90b.

The power amplifiers 11 and 12 and the 90° hybrid 50 are included in the semiconductor IC 81; the low-noise amplifiers 14 to 16 are included in the semiconductor IC 83; the switch circuit 41 is included in the semiconductor IC 82; and the switch circuit 42 is included in the semiconductor IC 84. At least one of the phase-shifting circuit 21 (capacitors 211 and 212 and inductor 213) and the phase-shifting circuit 22 (inductor 221 and capacitors 222 and 223) may be included in the semiconductor IC 82. Accordingly, part of the phase-shifting circuits 21 and 22 can be included in the semiconductor IC 82 in which the switch circuit 41 is formed, thereby miniaturizing the RF circuit 1.

### 5 Effects, Etc.

As described above, the RF circuit 1 according to the present embodiment includes: the antenna connection terminal 100; the 90° hybrid 50 having a first input end, a first output end, and a second output end, and configured to separate a signal in a transmission band of band A input to the first input end to output a first sub-band signal from the first output end and output a second sub-band signal from the second output end, the second sub-band signal having a phase relatively +90° with respect to the first sub-band signal; the power amplifier 11 having a second input end and a third output end, the second input end connected to the first output end; the power amplifier 12 having a third input end and a fourth output end, the third input end connected to the second output end; a combiner circuit that has a fourth input end, a fifth input end, and a fifth output end, and is configured to output, from the fifth output end, an output signal in band A generated by combining in phase a third sub-band signal in band A input from the fourth input end and a fourth sub-band signal in band A input from the fifth input end; the phase-shifting circuit 21 connected between the third output end and the fourth input end; the phase-shifting circuit 22 connected between the fourth output end and the fifth input end, and configured to set a passband phase of the signal in the transmission band of band A to be relatively −90° with respect to the phase-shifting circuit 21; the filter 61 connected between the fifth output end and the antenna connection terminal 100 or between the phase-shifting circuit 21 and the fourth input end, and having a passband containing the transmission band of band A; and the filter 64 connected to a path connecting the antenna connection terminal 100 and the filter 61, and having a passband containing a reception band of band B that can be transmitted simultaneously with band A, wherein the phase-shifting circuits 21 and 22 are configured such that a difference between a first reflection phase in the reception band of band B upon viewing the fifth output end from the third output end and a second reflection phase in the reception band of band B upon viewing the fifth output end from the fourth output end becomes 180°.

Accordingly, in the case of simultaneously transmitting the transmission signal in band A and the reception signal in band B, the reflection phase difference in the reception band of band B as viewed from the output ends of the two balanced power amplifiers 11 and 12 becomes 180°. This allows the reflection coefficient (F) of band B (attenuation band) in the filter 61, which has the transmission band of band A as its passband, to be increased. Therefore, this can suppress the leakage of the reception signal in band B to the two power amplifiers 11 and 12 through the filter 61, thereby improving the isolation between the transmission signal in band A and the reception signal in band B, which are transmitted simultaneously. Therefore, it is possible to provide the RF circuit 1, which is equipped with the balanced power amplifiers 11 and 12 and achieves highly efficient power combining as well as improved isolation between transmission and reception.

Additionally, for example, in the RF circuit 1, the phase-shifting circuit 21 is configured such that the passband phase in the transmission band of band A becomes +45°, and the phase-shifting circuit 22 is configured such that the passband phase in the transmission band of band A becomes −45°.

Accordingly, the first signal and the second signal, which are the two RF signals in band A, are combined in phase at the fifth output end, enabling high-efficiency fundamental wave power combining against load fluctuations.

Furthermore, for example, in the RF circuit 1, the phase-shifting circuit 21 includes the capacitor 211 connected between the third output end and the fourth input end, and the inductor 213 connected between the path connecting the capacitor 211 and the fourth input end and ground. The phase-shifting circuit 22 includes the inductor 221 connected between the fourth output end and the fifth input end, and the capacitor 223 connected between the path connecting the inductor 221 and the fifth input end and ground.

This allows the phase-shifting circuit 21 to have a configuration of a high-pass filter and to set the passband phase in the transmission band of band A to +45°. This also allows the phase-shifting circuit 22 to have a configuration of a low-pass filter and to set the passband phase in the transmission band of band A to −45°.

In addition, for example, the RF circuit 1 further includes the filter 63. The filter 61 is connected between the fifth output end and the antenna connection terminal 100. The combiner circuit includes the switch circuit 41, which has the terminal 41d (fourth input end), the terminal 41e (fifth input end), the terminal 41a (fifth output end), and, the terminal 41c (sixth output end), and which switches between the connection between the terminal 41d and the terminal 41a and the connection between the terminal 41e and the terminal 41a, and the connection between the terminal 41d and the terminal 41c and the connection between the terminal 41e and the terminal 41c. The filter 63 is connected to the terminal 41c.

Accordingly, the transmission signal in band A output from the power amplifier 11 and the transmission signal in band A output from the power amplifier 12 are combined in phase at the terminal 41a of the switch circuit 41, which switches between the filter 61 and the filter 63. Therefore, the switch circuit 41 uses the combiner circuit that combines balanced signals also as the switch circuit that switches between the filter connections, allowing for the miniaturization of the RF circuit 1.

Additionally, for example, in the RF circuit 1, the switch circuit 41 is included in the semiconductor IC 82, and at least part of the phase-shifting circuits 21 and 22 is included in the semiconductor IC 82.

Accordingly, part of the phase-shifting circuits can be included in the semiconductor IC 82 in which the switch circuit 41 is formed, thereby miniaturizing the RF circuit 1.

Also, for example, in the RF circuit 1, the filter 63 has a passband containing the transmission band of band B.

Accordingly, the transmission signal in band A output from the power amplifier 11 and the transmission signal in band A output from the power amplifier 12 are combined in phase at the terminal 41a of the switch circuit 41, which switches between the transmission signal in band A and the transmission signal in band B. Therefore, the switch circuit 41 uses the combiner circuit that combines balanced signals also as the switch circuit that switches between band A and band B, allowing for the miniaturization of the RF circuit 1.

Furthermore, for example, the RF circuit 1 further includes the filter 65 which is connected to a path connecting the antenna connection terminal 100 and the filter 63 and which has a passband containing the reception band of band A, and each of band A and band B is a band using time-division duplexing (TDD).

Accordingly, simultaneous transmission of the transmission signal in band A and the reception signal in band B and simultaneous transmission of the transmission signal in band B and the reception signal in band A can be realized.

Also, for example, in the RF circuit 1, the phase-shifting circuits 21 and 22 are configured such that a difference between a first reflection phase in the reception band of band B upon viewing the fifth output end from the third output end and a second reflection phase in the reception band of the band B upon viewing the fifth output end from the fourth output end becomes 180°. Furthermore, the phase-shifting circuits 21 and 22 are configured such that a difference between a third reflection phase in the reception band of band A upon viewing the sixth output end from the third output end and a fourth reflection phase in the reception band of band A upon viewing the sixth output end from the fourth output end becomes 180°.

Accordingly, the isolation between the transmission signal and the reception signal can be improved in both of the case of simultaneously transmitting and receiving the transmission signal in band A and the reception signal in band B, and the case of simultaneously transmitting and receiving the transmission signal in band B and the reception signal in band A.

In addition, for example, in the RF circuit 1, band A is band B41 for 4G-LTE or band n41 for 5G-NR, and band B is band B40 for 4G-LTE or band n40 for 5G-NR.

Additionally, for example, the RF circuit 1 further includes the low-noise amplifier 14 connected to the filter 64.

This can suppress the leakage of the reception signal in band B to the two power amplifiers 11 and 12 through the filter 61, thereby improving the isolation between the transmission signal in band A and the reception signal in band B, which are transmitted simultaneously. Therefore, the degradation of the reception sensitivity of the reception signal in band B output from the low-noise amplifier 14 can be suppressed.

Additionally, for example, the RF circuit 1 further includes the filter 62 having a passband containing the transmission band of band A. The filter 61 is connected between the phase-shifting circuit 21 and the terminal 42b of the switch circuit 42. The combiner circuit includes the switch circuit 42, which has the terminal 42b (fourth input end), the terminal 42c (fifth input end), and the terminal 42a (fifth output end), and which can connect the terminal 42b and the terminal 42a and connect the terminal 42c and the terminal 42a. The terminal 42a is connected to the antenna connection terminal 100, and the filter 62 is connected between the phase-shifting circuit 22 and the terminal 42c.

Accordingly, the transmission signal in band A output from the power amplifier 11 and the transmission signal in band A output from the power amplifier 12 are combined in phase at the terminal 42a of the switch circuit 42 connected to the antenna connection terminal 100 (third mode). Therefore, the switch circuit 42 uses the combiner circuit that combines balanced signals also as the antenna switch circuit, allowing for the miniaturization of the RF circuit 1.

Furthermore, the RF circuit 1A according to the first modification and the RF circuit 1B according to the second modification include: the antenna connection terminal 100; the 90° hybrid 54 having a first output end, a first input end, and a second input end, and configured to combine a first signal in a reception band of band B input to the first input end and a second signal in the reception band of band B input to the second input end, the second signal having a phase relatively +90° with respect to the first signal, and output a combined signal from the first output end; the low-noise amplifier 14 having a second output end and a third input end, the second output end connected to the first input end; the low-noise amplifier 15 having a third output end and a fourth input end, the third output end connected to the second input end; a splitter circuit that has a fourth output end, a fifth output end, and a fifth input end, and is configured to distribute power of a reception signal in band B input to the fifth input end to the fourth output end and the fifth output end; the phase-shifting circuit 23 connected between the third input end and the fourth output end; the phase-shifting circuit 24 connected between the fourth input end and the fifth output end, and configured to set a passband phase in the reception band of band B to be relatively −90° with respect to the phase-shifting circuit 23; the filter 64 connected between the fifth input end and the antenna connection terminal 100 or between the phase-shifting circuit 23 and the fourth output end, and having a passband containing the reception band of band B; and the filter 61 connected to a path connecting the antenna connection terminal 100 and the filter 64, and having a passband containing a transmission band of band A that can be transmitted simultaneously with band B, wherein the phase-shifting circuits 23 and 24 are configured such that a difference between a first reflection phase in the transmission band of band A upon viewing the fifth input end from the third input end and a second reflection phase in the transmission band of band A upon viewing the fifth input end from the fourth input end becomes 180°.

Accordingly, in the case of simultaneously transmitting the reception signal in band B and the transmission signal in band A, the reflection phase difference in the transmission band of band A as viewed from the input ends of the two balanced low-noise amplifiers 14 and 15 becomes 180°. This allows the reflection coefficient (F) of band A (attenuation band) in the filter 64, which has the reception band of band B as its passband, to be increased. Therefore, this can suppress the leakage of the transmission signal in band A to the two low-noise amplifiers 14 and 15 through the filter 64, thereby improving the isolation between the transmission signal in band A and the reception signal in band B, which are transmitted simultaneously, as well as suppressing the degradation of the reception sensitivity of band B. Therefore, it is possible to provide the RF circuits 1A and 1B, which are equipped with the balanced low-noise amplifiers 14 and 15 and achieves highly efficient power combining as well as improved isolation between transmission and reception.

In addition, for example, the RF circuit 1A further includes the filter 65. The filter 64 is connected between the terminal 43a and the antenna connection terminal 100. The splitter circuit includes the switch circuit 43, which has the terminal 43d (fourth output end), the terminal 43e (fifth output end), the terminal 43a (fifth input end), and the terminal 43b (sixth input end), and which switches between the connection between the terminal 43d and the terminal 43a and the connection between the terminal 43e and the terminal 43a, and the connection between the terminal 43d and the terminal 43b and the connection between the terminal 43e and the terminal 43b. The filter 65 is connected to the terminal 43b.

Accordingly, the reception signal in band B input to the low-noise amplifier 14 and the reception signal in band B input to the low-noise amplifier 15 are power-distributed at the terminal 43a of the switch circuit 43, which switches between the filter 64 and the filter 65. Therefore, the switch circuit 43 uses the splitter circuit that separates balanced signals also as the switch circuit that switches between the filter connections, allowing for the miniaturization of the RF circuit 1A.

Furthermore, for example, the RF circuits 1A and 1B further include the power amplifier 11 connected to the filter 61.

This can suppress the leakage of the transmission signal in band A output from the power amplifier 11 to the two low-noise amplifiers 14 and 15 through the filter 64, thereby improving the isolation between the transmission signal in band A and the reception signal in band B, which are transmitted simultaneously.

### Other Embodiments, Etc.

The RF circuit according to the embodiment of the present disclosure has been described above with reference to the embodiment and modifications, but the RF circuit according to the present disclosure is not limited to the embodiment and modifications described above. Another embodiment realized by combining any components from the above embodiment and modifications, as well as modifications obtained by applying various changes conceived by those skilled in the art without departing from the spirit of the present disclosure to the above embodiment and modifications, and various devices incorporating the above-mentioned RF circuit are also included in the present disclosure.

For example, in the amplifier circuit, RF circuit, and communication device according to the above embodiment and modifications, other circuit elements and wiring may be inserted between the circuit elements and the paths connecting the signal paths disclosed in the drawings.

Hereinafter, the characteristics of the RF circuits described based on the above embodiment will be described.

<1>

A radio-frequency circuit comprising:
a first antenna terminal;
a splitter that has a first input end, a first output end, and a second output end, and is configured to separate a signal in a transmission band of a first band input to the first input end to output a first sub-band signal from the first output end and output a second sub-band signal from the second output end, the second sub-band signal having a phase relatively +90° with respect to the first sub-band signal;
a first power amplifier that has a second input end and a third output end, the second input end connected to the first output end;
a second power amplifier that has a third input end and a fourth output end, the third input end connected to the second output end;
a combiner circuit that has a fourth input end, a fifth input end, and a fifth output end, and is configured to output, from the fifth output end, an output signal in the first band generated by combining in phase a third sub-band signal in the first band input from the fourth input end and a fourth sub-band signal in the first band input from the fifth input end;
a first phase-shifting circuit connected between the third output end and the fourth input end;
a second phase-shifting circuit that is connected between the fourth output end and the fifth input end, and is configured such that a passband phase of the signal in the transmission band of the first band becomes relatively −90° with respect to the first phase-shifting circuit;
a first filter that is connected between the fifth output end and the first antenna terminal or between the first phase-shifting circuit and the fourth input end, and has a passband containing the transmission band of the first band; and
a second filter that is connected to a path connecting the first antenna terminal and the first filter, and has a passband containing a reception band of a second band that can be transmitted simultaneously with the first band,
wherein the first phase-shifting circuit and the second phase-shifting circuit are configured such that
a difference between a first reflection phase in the reception band of the second band upon viewing the fifth output end from the third output end and a second reflection phase in the reception band of the second band upon viewing the fifth output end from the fourth output end becomes 1800.
   <2>

The radio-frequency circuit according to <1>, wherein:
the first phase-shifting circuit is configured such that a passband phase in the transmission band of the first band becomes +45°; and
the second phase-shifting circuit is configured such that a passband phase in the transmission band of the first band becomes −45°.
   <3>

The radio-frequency circuit according to <2>, wherein:
the first phase-shifting circuit includes
a first capacitor connected between the third output end and the fourth input end, and
a first inductor connected between a path connecting the first capacitor and the fourth input end and ground; and
the second phase-shifting circuit includes
a second inductor connected between the fourth output end and the fifth input end, and
a second capacitor connected between a path connecting the second inductor and the fifth input end and ground.
   <4>

The radio-frequency circuit according to any of <1> to <3> further comprising:
a third filter,
wherein the first filter is connected between the fifth output end and the first antenna terminal,
the combiner circuit includes
a switch circuit that has the fourth input end, the fifth input end, the fifth output end, and a sixth output end, and switches between a connection between the fourth input end and the fifth output end and a connection between the fifth input end and the fifth output end, and a connection between the fourth input end and the sixth output end and a connection between the fifth input end and the sixth output end, and
the third filter is connected to the sixth output end.
   <5>

The radio-frequency circuit according to <4>, wherein:
the switch circuit is included in a semiconductor IC; and
at least part of the first phase-shifting circuit and the second phase-shifting circuit is included in the semiconductor IC.
   <6>

The radio-frequency circuit according to <4> or <5>, wherein the third filter has a passband containing a transmission band of the second band.

<7>

The radio-frequency circuit according to <6>, further comprising:
a fourth filter that is connected to a path connecting the first antenna terminal and the third filter, and has a passband containing a reception band of the first band,
wherein each of the first band and the second band is a band using time-division duplexing (TDD).
   <8>

The radio-frequency circuit according to <7>, wherein:
the first phase-shifting circuit and the second phase-shifting circuit are configured such that
a difference between the first reflection phase in the reception band of the second band upon viewing the fifth output end from the third output end and the second reflection phase in the reception band of the second band upon viewing the fifth output end from the fourth output end becomes 180°, and a difference between a third reflection phase in a reception band of the first band upon viewing the sixth output end from the third output end and a fourth reflection phase in the reception band of the first band upon viewing the sixth output end from the fourth output end becomes 180°.
   <9>

The radio-frequency circuit according to any of <1> to <8>, wherein:
the first band is band B41 for 4G-LTE or band n41 for 5G-NR; and
the second band is band B40 for 4G-LTE or band n40 for 5G-NR.
   <10>

The radio-frequency circuit according to any one of <1> to <9>, further comprising a low-noise amplifier connected to the second filter.

<11>

The radio-frequency circuit according to any of <1> to <3> further comprising:
a fifth filter that has a passband containing the transmission band of the first band,
wherein the first filter is connected between the first phase-shifting circuit and the fourth input end,
the combiner circuit includes
a switch circuit that has the fourth input end, the fifth input end, and the fifth output end, and is capable of connecting the fourth input end and the fifth output end, and connecting the fifth input end and the fifth output end,
the fifth output end is connected to the first antenna terminal, and
the fifth filter is connected between the second phase-shifting circuit and the fifth input end.
   <12>

A radio-frequency circuit comprising:
a first antenna terminal;
a combiner that has a first output end, a first input end, and a second input end, and is configured to combine a first signal in a reception band of a first band input to the first input end and a second signal in the reception band of the first band input to the second input end, the second signal having a phase relatively +90° with respect to the first signal, and output a combined signal from the first output end;
a first low-noise amplifier that has a second output end and a third input end, the second output end connected to the first input end;
a second low-noise amplifier that has a third output end and a fourth input end, the third output end connected to the second input end;
a splitter circuit that has a fourth output end, a fifth output end, and a fifth input end, and is configured to distribute power of a reception signal in the first band input to the fifth input end to the fourth output end and the fifth output end;
a first phase-shifting circuit connected between the third input end and the fourth output end;
a second phase-shifting circuit that is connected between the fourth input end and the fifth output end, and is configured such that a passband phase in the reception band of the first band becomes relatively −90° with respect to the first phase-shifting circuit;
a first filter that is connected between the fifth input end and the first antenna terminal or between the first phase-shifting circuit and the fourth output end, and has a passband containing the reception band of the first band; and
a second filter that is connected to a path connecting the first antenna terminal and the first filter, and has a passband containing a transmission band of a second band that can be transmitted simultaneously with the first band,
wherein the first phase-shifting circuit and the second phase-shifting circuit are configured such that
a difference between a first reflection phase in the transmission band of the second band upon viewing the fifth input end from the third input end and a second reflection phase in the transmission band of the second band upon viewing the fifth input end from the fourth input end becomes 180°.
   <13>

The radio-frequency circuit according to <12>, further comprising:
a third filter,
wherein the first filter is connected between the fifth input end and the first antenna terminal,
the splitter circuit includes
a switch circuit that has the fourth output end, the fifth output end, the fifth input end, and a sixth input end, and switches between a connection between the fourth output end and the fifth input end and a connection between the fifth output end and the fifth input end, and a connection between the fourth output end and the sixth input end and a connection between the fifth output end and the sixth input end, and
the third filter is connected to the sixth input end.
   <14>

The radio-frequency circuit according to <12> or <13>, further comprising a power amplifier connected to the second filter.

The present disclosure can be widely used in communication equipment such as mobile phones, as an amplifying circuit, a radio-frequency circuit, or a communication device arranged in the front-end portion.

What is claimed is:

1. A radio-frequency circuit comprising:
a first antenna terminal;
a splitter that has a first input end, a first output end, and a second output end, and is configured to separate a signal in a transmission band of a first band input to the first input end to output a first sub-band signal from the first output end and output a second sub-band signal from the second output end, the second sub-band signal having a phase relatively +90° with respect to the first sub-band signal;
a first power amplifier that has a second input end and a third output end, the second input end connected to the first output end;
a second power amplifier that has a third input end and a fourth output end, the third input end connected to the second output end;
a combiner circuit that has a fourth input end, a fifth input end, and a fifth output end, and is configured to output, from the fifth output end, an output signal in the first band generated by combining in phase a third sub-band signal in the first band input from the fourth input end and a fourth sub-band signal in the first band input from the fifth input end;
a first phase-shifting circuit connected between the third output end and the fourth input end;
a second phase-shifting circuit that is connected between the fourth output end and the fifth input end, and is configured such that a passband phase of the signal in the transmission band of the first band becomes relatively −90° with respect to the first phase-shifting circuit;
a first filter that is connected between the fifth output end and the first antenna terminal or between the first phase-shifting circuit and the fourth input end, and has a passband containing the transmission band of the first band; and
a second filter that is connected to a path connecting the first antenna terminal and the first filter, and has a passband containing a reception band of a second band that can be transmitted simultaneously with the first band,
wherein the first phase-shifting circuit and the second phase-shifting circuit are configured such that
a difference between a first reflection phase in the reception band of the second band upon viewing the fifth output end from the third output end and a second reflection phase in the reception band of the second band upon viewing the fifth output end from the fourth output end becomes 180°.

2. The radio-frequency circuit according to claim 1, wherein:
the first phase-shifting circuit is configured such that a passband phase in the transmission band of the first band becomes +45°; and
the second phase-shifting circuit is configured such that a passband phase in the transmission band of the first band becomes −45°.

3. The radio-frequency circuit according to claim 2, wherein:
the first phase-shifting circuit includes
a first capacitor connected between the third output end and the fourth input end, and
a first inductor connected between a path connecting the first capacitor and the fourth input end and ground; and
the second phase-shifting circuit includes
a second inductor connected between the fourth output end and the fifth input end, and
a second capacitor connected between a path connecting the second inductor and the fifth input end and ground.

4. The radio-frequency circuit according to claim 3, further comprising:
a third filter,
wherein the first filter is connected between the fifth output end and the first antenna terminal,
the combiner circuit includes
a switch circuit that has the fourth input end, the fifth input end, the fifth output end, and a sixth output end, and switches between a connection between the fourth input end and the fifth output end and a connection between the fifth input end and the fifth output end, and a connection between the fourth input end and the sixth output end and a connection between the fifth input end and the sixth output end, and
the third filter is connected to the sixth output end.

5. The radio-frequency circuit according to claim 4, wherein:
the switch circuit is included in a semiconductor IC; and
at least part of the first phase-shifting circuit and the second phase-shifting circuit is included in the semiconductor IC.

6. The radio-frequency circuit according to claim 4, wherein:
the third filter has a passband containing a transmission band of the second band.

7. The radio-frequency circuit according to claim 6, further comprising:
a fourth filter that is connected to a path connecting the first antenna terminal and the third filter, and has a passband containing a reception band of the first band,
wherein each of the first band and the second band is a band using time-division duplexing (TDD).

8. The radio-frequency circuit according to claim 7, wherein:
the first phase-shifting circuit and the second phase-shifting circuit are configured such that
a difference between the first reflection phase in the reception band of the second band upon viewing the fifth output end from the third output end and the second reflection phase in the reception band of the second band upon viewing the fifth output end from the fourth output end becomes 180°, and a difference between a third reflection phase in a reception band of the first band upon viewing the sixth output end from the third output end and a fourth reflection phase in the reception band of the first band upon viewing the sixth output end from the fourth output end becomes 180°.

9. The radio-frequency circuit according to claim 3, wherein:
the first band is band B41 for 4G-LTE or band n41 for 5G-NR, and
the second band is band B40 for 4G-LTE or band n40 for 5G-NR.

10. The radio-frequency circuit according to claim 3, further comprising:
a low-noise amplifier connected to the second filter.

11. The radio-frequency circuit according to claim 3, further comprising:
a fifth filter that has a passband containing the transmission band of the first band,
wherein the first filter is connected between the first phase-shifting circuit and the fourth input end,
the combiner circuit includes
a switch circuit that has the fourth input end, the fifth input end, and the fifth output end, and is capable of connecting the fourth input end and the fifth output end, and connecting the fifth input end and the fifth output end,
the fifth output end is connected to the first antenna terminal, and
the fifth filter is connected between the second phase-shifting circuit and the fifth input end.

12. A radio-frequency circuit comprising:
a first antenna terminal;
a combiner that has a first output end, a first input end, and a second input end, and is configured to combine a first signal in a reception band of a first band input to the first input end and a second signal in the reception band of the first band input to the second input end, the second signal having a phase relatively +90° with respect to the first signal, and output a combined signal from the first output end;
a first low-noise amplifier that has a second output end and a third input end, the second output end connected to the first input end;
a second low-noise amplifier that has a third output end and a fourth input end, the third output end connected to the second input end;
a splitter circuit that has a fourth output end, a fifth output end, and a fifth input end, and is configured to distribute power of a reception signal in the first band input to the fifth input end to the fourth output end and the fifth output end;
a first phase-shifting circuit connected between the third input end and the fourth output end;
a second phase-shifting circuit that is connected between the fourth input end and the fifth output end, and is configured such that a passband phase in the reception band of the first band becomes relatively −90° with respect to the first phase-shifting circuit;
a first filter that is connected between the fifth input end and the first antenna terminal or between the first phase-shifting circuit and the fourth output end, and has a passband containing the reception band of the first band; and
a second filter that is connected to a path connecting the first antenna terminal and the first filter, and has a passband containing a transmission band of a second band that can be transmitted simultaneously with the first band,
wherein the first phase-shifting circuit and the second phase-shifting circuit are configured such that
a difference between a first reflection phase in the transmission band of the second band upon viewing the fifth input end from the third input end and a second reflection phase in the transmission band of the second band upon viewing the fifth input end from the fourth input end becomes 180°.

13. The radio-frequency circuit according to claim 12, further comprising:
a third filter,
wherein the first filter is connected between the fifth input end and the first antenna terminal,
the splitter circuit includes
a switch circuit that has the fourth output end, the fifth output end, the fifth input end, and a sixth input end, and switches between a connection between the fourth output end and the fifth input end and a connection between the fifth output end and the fifth input end, and a connection between the fourth output end and the sixth input end and a connection between the fifth output end and the sixth input end, and
the third filter is connected to the sixth input end.

14. The radio-frequency circuit according to claim 13, further comprising:
a power amplifier connected to the second filter.

15. The radio-frequency circuit according to claim 12, further comprising:
a power amplifier connected to the second filter.

16. The radio-frequency circuit according to claim 1, further comprising:
a third filter,
wherein the first filter is connected between the fifth output end and the first antenna terminal,
the combiner circuit includes
a switch circuit that has the fourth input end, the fifth input end, the fifth output end, and a sixth output end, and switches between a connection between the fourth input end and the fifth output end and a connection between the fifth input end and the fifth output end, and a connection between the fourth input end and the sixth output end and a connection between the fifth input end and the sixth output end, and
the third filter is connected to the sixth output end.

17. The radio-frequency circuit according to claim 16, wherein:
the switch circuit is included in a semiconductor IC; and
at least part of the first phase-shifting circuit and the second phase-shifting circuit is included in the semiconductor IC.

18. The radio-frequency circuit according to claim 2, further comprising:
a third filter,
wherein the first filter is connected between the fifth output end and the first antenna terminal,
the combiner circuit includes
a switch circuit that has the fourth input end, the fifth input end, the fifth output end, and a sixth output end, and switches between a connection between the fourth input end and the fifth output end and a connection between the fifth input end and the fifth output end, and a connection between the fourth input end and the sixth output end and a connection between the fifth input end and the sixth output end, and
the third filter is connected to the sixth output end.

19. The radio-frequency circuit according to claim 18, wherein:
the switch circuit is included in a semiconductor IC; and
at least part of the first phase-shifting circuit and the second phase-shifting circuit is included in the semiconductor IC.

20. The radio-frequency circuit according to claim 1, further comprising:
a fifth filter that has a passband containing the transmission band of the first band,
wherein the first filter is connected between the first phase-shifting circuit and the fourth input end,
the combiner circuit includes
a switch circuit that has the fourth input end, the fifth input end, and the fifth output end, and is capable of connecting the fourth input end and the fifth output end, and connecting the fifth input end and the fifth output end,
the fifth output end is connected to the first antenna terminal, and
the fifth filter is connected between the second phase-shifting circuit and the fifth input end.
